(19) United States
(12) Patent Application Publication
(10) Pub. No.: US 2025/0070531 A1
(43) Pub. Date: Feb. 27, 2025

(54) SURFACE EMITTING LASER

(71) Applicant: SONY GROUP CORPORATION, TOKYO (JP)

(72) Inventors: MIKIHIRO YOKOZEKI, TOKYO (JP); YOSHIRO TAKIGUCHI, TOKYO (JP); HIROSHI NAKAJIMA, TOKYO (JP); TOMOMASA WATANABE, TOKYO (JP); MICHINORI SHIOMI, TOKYO (JP)

(21) Appl. No.: 18/725,044

(22) PCT Filed: Nov. 18, 2022
(86) PCT No.: PCT/JP2022/042793

§ 371 Date: Jun. 27, 2024

(30) Foreign Application Priority Data
Jan. 7, 2022 (JP) 2022-001701

(51) Int. Cl. H01S 5/024; H01S 5/183; H01S 5/42

(52) U.S. Cl. CPC H01S 5/02461; H01S 5/18369; H01S 5/18377; H01S 5/423

(57) ABSTRACT

A surface emitting laser that allows for improved heat dissipation is provided. The surface emitting laser according to the present technology includes a semiconductor multilayer film reflector, a reflector, an active layer provided between the semiconductor multilayer film reflector and the reflector, a metal film provided at a back surface of the semiconductor multilayer film reflector which is a surface on an opposite side to the side of the active layer or having a part provided on a virtual surface including the back surface on the opposite side to the side of the active layer and a further part provided in and/or around the semiconductor multilayer film reflector. According to the present technology a surface emitting laser that allows for improved heat dissipation can be provided.

### TECHNICAL FIELD

The technology according to the present disclosure (hereinafter also referred to as the “present technology) relates to a surface emitting laser.

### BACKGROUND ART

Some known conventional surface emitting lasers are manufactured with a material with high heat dissipation on the side (lower reflector side) of the active layer opposite to the upper reflector side (see for example PTL 1 and NPL 1).

### CITATION LIST

### Patent Literature

### PTL 1

JP 2015-28995A

### NPL 1

Robert Shau, Markus Ortsiefer, Juergen Rosskopf, Gerhard Boehm, Christian Lauer, Markus Maute, Markus-Christian Amann, “Long-wavelength InP-based VCSELs with buried tunnel junction: properties and applications,” Proc. SPIE 5364, Vertical-Cavity Surface-Emitting Lasers VIII, (16 Jun. 2004); doi: 10.1117/12.538668.

### SUMMARY

### Technical Problem

However, the conventional surface emitting lasers have room for improvement in terms of heat dissipation.

It is therefore a main object of the present technology to provide a surface emitting laser that allows for improved heat dissipation.

### Solution to Problem

A surface emitting laser provided according to the present technology includes a semiconductor multilayer film reflector, a reflector,
an active layer provided between the semiconductor multilayer film reflector and the reflector, and
a metal film provided at a back surface of the semiconductor multilayer film reflector which is a surface on an opposite side to the side of the active layer or having a part provided on a virtual surface including the back surface on the opposite side to the side of the active layer and a further part provided in and/or around the semiconductor multilayer film reflector.

The semiconductor multilayer film reflector may include amorphous layers and mixed crystal layers alternately stacked on each other.

Each of the amorphous layer may be an InP layer, and each of the mixed crystal layer may be an AlGaInAs layer.

The metal film may have the part provided on the virtual surface including the back surface on the opposite side to the side of the active layer and the further part provided in and/or around the semiconductor multilayer film reflector, and the further part of the metal film may be in contact with a side surface of the semiconductor multilayer film reflector.

A hole may be provided at the back surface of the semiconductor multilayer film reflector, and the further part of the metal film may be fitted in the hole.

The further part of the metal film may be in contact with an inner surface of the hole.

The hole may penetrate the semiconductor multilayer film reflector.

The hole does not have to penetrate the semiconductor multilayer film reflector.

The hole may have a shape at least partly tapered or reversely tapered in side view.

The hole may be provided around a region of the semiconductor multilayer film reflector corresponding to an emission region of the active layer.

At least one of the holes may be provided to surround the region of the semiconductor multilayer film reflector.

A plurality of the holes may be provided.

First and second electrodes configured to inject current to the active layer may be provided on a side of the semiconductor multilayer film reflector opposite to the back surface side.

The back surface of the semiconductor multilayer film reflector may be one surface of one of the amorphous layers.

The one of the amorphous layer may have a thickness different from that of another amorphous layer of the semiconductor multilayer film reflector.

The metal film may be made of one of Au, Ag, and Al.

The metal film may have a stacked structure including a plurality of metal layers of different kinds of metal stacked on each other.

The amorous layer of a part of the semiconductor multilayer film reflector may have an optical thickness represented by (m+2)λ/4(m>1) where the surface emitting laser has an oscillation wavelength λ.

The metal film and a substrate may be bonded through another metal film.

The reflector may be a dielectric multilayer film reflector.

### BRIEF DESCRIPTION OF DRAWINGS

FIG. 1A is a cross-sectional view of a surface emitting laser according to Example 1 of an embodiment of the present technology. FIG. 1B is a plan view of a metal film in the surface emitting laser according to Example 1 of the embodiment of the present technology.

FIG. 2 is a table indicating the thermal conductivity of a plurality of materials.

FIG. 3 is a graph indicating a relation between optical wavelengths and reflectance.

FIG. 4 is a flowchart for illustrating an example of a method for manufacturing the surface emitting laser in FIG. 1A.

FIGS. 5A and 5B are cross-sectional views for illustrating each step in the method for manufacturing the surface emitting laser in FIG. 1A.

FIGS. 6A and 6B are cross-sectional views for illustrating each step in the method for manufacturing the surface emitting laser in FIG. 1A.

FIGS. 7A and 7B are cross-sectional views for illustrating each step in the method for manufacturing the surface emitting laser in FIG. 1A.

FIGS. 8A and 8B are cross-sectional views for illustrating each step in the method for manufacturing the surface emitting laser in FIG. 1A.

FIG. 9 is a cross-sectional view for illustrating each step in the method for manufacturing the surface emitting laser in FIG. 1A.

FIG. 10A is a cross-sectional view of a surface emitting laser according to Example 2 of the embodiment according to the present technology. FIG. 10B is a plan view of a semiconductor multilayer film reflector in which a part of the metal film of the surface emitting laser according to Example 2 of the embodiment of the present technology is provided.

FIG. 11 is a flowchart for illustrating an example of a method for manufacturing the surface emitting laser in FIG. 10A.

FIGS. 12A and 12B are cross-sectional views for illustrating each step in the method for manufacturing the surface emitting laser in FIG. 10A.

FIGS. 13A and 13B are cross-sectional views for illustrating each step in the method for manufacturing the surface emitting laser in FIG. 10A.

FIGS. 14A and 14B are cross-sectional views of a surface emitting laser according to Example 3 of the embodiment of the present technology (part 1 and part 2).

FIG. 15 is a plan view of a semiconductor multilayer film reflector in which a part of a metal film of the surface emitting laser according to Example 3 of the embodiment of the present technology is provided.

FIG. 16A is a cross-sectional view of a surface emitting laser according to Example 4 of the embodiment of the present technology FIG. 16B is a plan view of the semiconductor multilayer film reflector in which a part of a metal film of the surface emitting laser according to Example 4 of the embodiment of the present technology is provided.

FIGS. 17A and 17B are cross-sectional views (part 1 and part 2) of a surface emitting laser according to Example 5 of the embodiment of the present technology.

FIG. 18 is a plan view of a semiconductor multilayer film reflector in which a part of a metal film of the surface emitting laser according to Example 5 of the embodiment of the present technology is provided.

FIG. 19A is a cross-sectional view of a surface emitting laser according to Example 6 of the embodiment of the present technology FIG. 19B is a plan view of a semiconductor multilayer film reflector in which a part of a metal film of the surface emitting laser according to Example 6 of the embodiment of the present technology is provided.

FIG. 20A is a cross-sectional view of a surface emitting laser according to Example 7 of the embodiment of the present technology. FIG. 20B is a plan view of a semiconductor multilayer film reflector in which a part of a metal film of the surface emitting laser according to Example 7 of the embodiment of the present technology is provided.

FIG. 21A is a cross-sectional view of a surface emitting laser according to Example 8 of the embodiment of the present technology. FIG. 21B is a plan view of a semiconductor multilayer film reflector in which a part of a metal film of the surface emitting laser according to Example 8 of the embodiment of the present technology is provided.

FIG. 22 is a flowchart for illustrating an example of a method for manufacturing the surface emitting laser in FIG. 21A.

FIGS. 23A and 23B are cross-sectional views for illustrating each step in the method for manufacturing the surface emitting laser in FIG. 21A.

FIGS. 24A and 24B are cross-sectional views for illustrating each step in the method for manufacturing the surface emitting laser in FIG. 21A.

FIGS. 25A and 25B are cross-sectional views for illustrating each step in the method for manufacturing the surface emitting laser in FIG. 21A.

FIGS. 26A and 26B are cross-sectional views for illustrating each step in the method for manufacturing the surface emitting laser in FIG. 21A.

FIG. 27A is a cross-sectional view of a surface emitting laser according to Example 9 of the embodiment of the present technology. FIG. 27B is a plan view of a semiconductor multilayer film reflector in which a part of a metal film of the surface emitting laser according to Example 9 of the embodiment of the present technology is provided.

FIG. 28A illustrates an advantageous effect of the surface emitting laser in FIG. 28A.

FIG. 29A is a cross-sectional view of a surface emitting laser according to Example 10 of the embodiment of the present technology. FIG. 29B is a plan view of a semiconductor multilayer film reflector in which a part of a metal film of the surface emitting laser according to Example 10 of the embodiment of the present technology is provided.

FIG. 30A is a cross-sectional view of a surface emitting laser according to Example 11 of the embodiment of the present technology. FIG. 30B is a plan view of a semiconductor multilayer film reflector in which a part of a metal film of the surface emitting laser according to Example 11 of the embodiment of the present technology is provided.

FIG. 31A is a cross-sectional view of a surface emitting laser according to Example 12 of the embodiment of the present technology. FIG. 31B is a plan view of a semiconductor multilayer film reflector in which a part of the metal film of the surface emitting laser according to Example 12 of the embodiment of the present technology is provided.

FIG. 32A is a cross-sectional view of a surface emitting laser according to Example 13 of the embodiment of the present technology. FIG. 32B is a plan view of a semiconductor multilayer film reflector in which a part of a metal film of the surface emitting laser according to Example 13 of the embodiment of the present technology is provided.

FIG. 33A is a cross-sectional view of a surface emitting laser according to Example 14 of the embodiment of the present technology. FIG. 33B is a plan view of a semiconductor multilayer film reflector around which a part of a metal film of the surface emitting laser according to Example 14 of the embodiment of the present technology is provided.

FIG. 34A is a cross-sectional view of a surface emitting laser according to Example 15 of the embodiment of the present technology. FIG. 34B is a plan view of a semiconductor multilayer film reflector in which a part of a metal film of the surface emitting laser according to Example 15 of the embodiment of the present technology is provided.

FIG. 35A is a cross-sectional view of a surface emitting laser according to Example 16 of the embodiment of the present technology. FIG. 35B is a plan view of a semiconductor multilayer film reflector in which a part of a metal film of the surface emitting laser according to Example 16 of the embodiment of the present technology is provided.

FIG. 36A is a cross-sectional view of a surface emitting laser according to Example 17 of the embodiment of the present technology. FIG. 36B is a plan view of a semiconductor multilayer film reflector in which a part of a metal film of the surface emitting laser according to Example 17 of the embodiment of the present technology is provided.

FIG. 37A is a cross-sectional view of a surface emitting laser according to Example 18 of the embodiment of the present technology. FIG. 37B is a plan view of a semiconductor multilayer film reflector around which a part of the metal film of the surface emitting laser according to Example 18 of the embodiment of the present technology is provided.

FIG. 38A is a cross-sectional view of a surface emitting laser according to Example 19 of the embodiment of the present technology. FIG. 38B is a plan view of a semiconductor multilayer film reflector in which a part of a metal film of the surface emitting laser according to Example 19 of the embodiment of the present technology is provided.

FIG. 39A is a cross-sectional view of a surface emitting laser according to Example 20 of the embodiment of the present technology. FIG. 39B is a plan view of a semiconductor multilayer film reflector in which a part of a metal film of the surface emitting laser according to Example 20 of the embodiment of the present technology is provided.

FIG. 40 is a cross-sectional view of a surface emitting laser array including a plurality of surface emitting lasers in FIG. 1A arranged in array form.

FIG. 41 is a cross-sectional view of a surface emitting laser array including a plurality of surface emitting lasers in FIG. 10A arranged in array form.

FIG. 42 illustrates an example of application of a surface emitting laser according to the present technology to a distance measurement device.

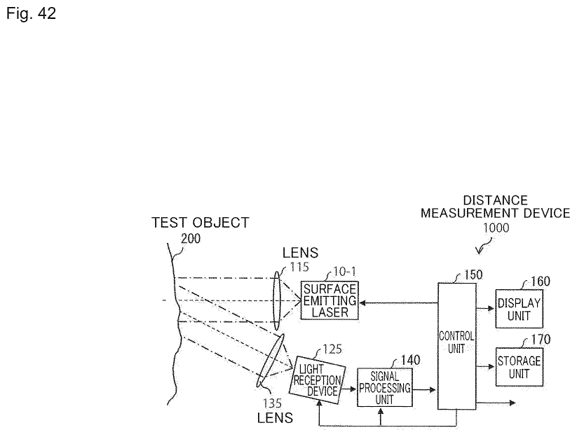

FIG. 43 is a block diagram illustrating an exemplary schematic configuration of a vehicle control system.

FIG. 44 is a view for illustrating an example of the installation position of the distance measurement device.

### DESCRIPTION OF EMBODIMENTS

Preferred embodiments of the present technology will be described in detail with reference to the accompanying figures below. In the present specification and the drawings, components having substantially the same functional configuration will be denoted by the same reference numerals, and thus repeated descriptions thereof will be omitted. The following description of the embodiments is about typical embodiments of the present technology and the scope of the present technology shall not be limited narrowly by the same. If the specification indicates that a surface emitting laser according to the present technology exhibits a plurality of advantageous effects, the surface emitting laser according to the present technology needs only exhibit at least one advantageous effect.

The advantageous effects described in the specification are merely illustrative and should not be construed as limiting, and there may be other advantageous effects.

The description will be made in the following order.
0. Introduction
1. Surface Emitting Laser According to Example 1 of an Embodiment of the Present Technology
2. Surface Emitting Laser According to Example 2 of the Embodiment of the Present Technology
3. Surface Emitting Laser According to Example 3 of the Embodiment of the Present Technology
4. Surface Emitting Laser According to Example 4 of the Embodiment of the Present Technology
5. Surface Emitting Laser According to Example 5 of the Embodiment of the Present Technology
6. Surface Emitting Laser According to Example 6 of the Embodiment of the Present Technology
7. Surface Emitting Laser According to Example 7 of the Embodiment of the Present Technology
8. Surface Emitting Laser According to Example 8 of the Embodiment of the Present Technology
9. Surface Emitting Laser According to Example 9 of the Embodiment of the Present Technology
10. Surface Emitting Laser According to Example 10 of the Embodiment of the Present Technology
11. Surface Emitting Laser According to Example 11 of the Embodiment of the Present Technology
12. Surface Emitting Laser According to Example 12 of the Embodiment of the Present Technology
13. Surface Emitting Laser According to Example 13 of the Embodiment of the Present Technology
14. Surface Emitting Laser According to Example 14 of the Embodiment of the Present Technology
15. Surface Emitting Laser According to Example 15 of the Embodiment of the Present Technology
16. Surface Emitting Laser According to Example 16 of the Embodiment of the Present Technology
17. Surface Emitting Laser According to Example 17 of the Embodiment of the Present Technology
18. Surface Emitting Laser According to Example 18 of the Embodiment of the Present Technology
19. Surface Emitting Laser According to Example 19 of the Embodiment of the Present Technology
20. Surface Emitting Laser According to Example 20 of the Embodiment of the Present Technology
21. Modification of Present Technology
22. Example of Application to Electronic Device
23. Example of Application of Surface Emitting Laser to Distance Measurement Device
24. Example of Application of Distance Measurement Device to Mobile Body

### <0. Introduction>

In recent years, infrared surface emitting lasers have been developed for 3D sensing or face recognition. The main band currently used is the 940 nm band, and it is desired that the available wavelength becomes longer in the future. In particular, the 1.4 μm band is advantageous in that the band is an eye-safe band having a significantly high damage threshold to the eye, and also noise is lower due to the low background of sunlight. Meanwhile, InP-based surface emitting lasers suitable for longer wavelengths equal to or higher than 1.3 μm have major problems such as difficulty in forming epi-DBRs with good heat dissipation and narrow stopband widths due to the small refractive index difference of the materials of the DBRs, which results in characteristic fluctuations and lower yields according to temperature.

Therefore, the inventors have developed the surface emitting laser according to the present technology as a surface emitting laser with excellent heat dissipation. The surface emitting laser according to the present technology can also have a large effective stopband width. Furthermore, the surface-emitting laser according to the present technology has excellent mass-producibility and can be expected to find applications in various technological fields.

Hereinafter, surface emitting lasers according to an embodiment of the present technology will be described in detail with reference to examples.

### <1. Surface Emitting Laser According to Example 1 of an Embodiment of the Present Technology>

Hereinafter, a surface emitting laser 10-1 according to Example 1 of an embodiment of the present technology will be described.

### <<Configuration of Surface Emitting Laser>>

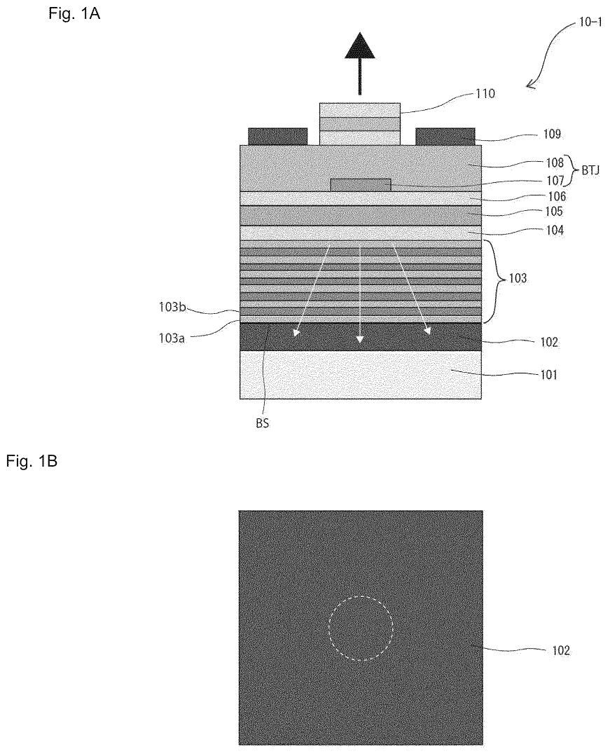

FIG. 1A is a cross-sectional view of a surface emitting laser 10-1 according to Example 1 of the embodiment of the present technology. FIG. 1B is a plan view of a metal film 102 of the surface emitting laser 10-1. In the following description, the upper part of the sectional view such as 1A will be referred to as the upper side and the lower part will be referred to as the lower side for the sake of convenience.

A shown in FIG. 1A, the surface emitting laser 10-1 is a vertical resonance type surface emitting laser which has a resonator having a semiconductor structure including an active layer 105 sandwiched between a first reflector and a second reflector. An example of the surface emitting laser 10-1 is an InP-based surface emitting laser. The surface emitting laser 10-1 has an oscillation wavelength λ of at least 900 nm. The surface emitting laser 10-1 is driven for example by a laser driver.

The surface emitting laser 10-1 includes a semiconductor multilayer film reflector 103 that constitutes a part of the first reflector, a reflector 110 as a second reflector, the active layer 105 provided between the semiconductor multilayer film reflector 103 and the reflector 110, a metal film 102 provided on the back surface BS which is a surface of the semiconductor multilayer film reflector 103 on the side (lower side) opposite to the side of the active layer 105 (upper side) to form a further part of the first reflector by way of illustration.

The surface emitting laser 10-1 further includes, as an example, a substrate 101 bonded to the opposite side of the semiconductor multilayer film reflector 103 of the metal film 102.

The surface emitting laser 10-1 further includes, as an example, a first cladding layer 104 provided between the semiconductor multilayer film reflector 103 and the active layer 105.

The surface emitting laser 10-1 further includes, as an example, a second cladding layer 106 provided between the active layer 105 and the reflector 110.

The surface emitting laser 10-1 further includes, as an example, a tunnel junction layer 107 provided on the second cladding layer 106.

The surface emitting laser 10-1 further includes, as an example, an embedding layer 108 provided between the second cladding layer 106 and the reflector 110 and embeds an area around the tunnel junction layer 107. A BTJ (Buried Tunnel Junction) including the tunnel junction layer 107 and the embedding layer 108 is formed.

The surface emitting laser 10-1 further includes, as an example, an anode electrode 109 provided around the reflector 110 on the embedding layer 108.

The metal film 102 also functions for example as a cathode electrode.

### (Substrate)

The substrate 101 may be any substrate such as a semiconductor substrate (e.g., silicon substrate), a semi-insulating substrate, or ab insulating substrate. The substrate 101 is preferably made of a material with high thermal conductivity (high heat dissipation). The substrate 101 is a holding substrate that holds the resonator of the surface emitting laser 10-1.

### (First and Second Cladding Layers)

The first cladding layer 104 may be an n-InP layer. The second cladding layer 106 may be a p-InP layer.

### (BTJ)

The BTJ includes the tunnel junction layer 107 and the embedding layer 108 as described above. The BTJ is located on the active layer 105 on the side of the anode electrode 109. In other words, the BTJ is located upstream of the active layer 105 in the current path from the anode electrode 109 to the cathode electrode (metal film 102).

For example, the embedding layer 108 may be made of an InP-based compound semiconductor (e.g., n-InP layer).

The tunnel junction layer 107 is provided in a mesa shape on the second cladding layer 106. The tunnel junction layer 107 has significantly lower resistance (very high carrier conductivity) than the surrounding embedding layer 108 and serves as a current-passing region. The tunnel junction layer 107 is also a heat-generating part.

The tunnel junction layer 107 includes p-type and n-type semiconductor regions stacked on each other. Here, the p-type semiconductor region is provided on the n-type semiconductor region on the side of the active layer 105 (lower side). For example, the p-type semiconductor region is made of p-type AlInGaAs-based compound semiconductor highly doped with C (carbon). The n-type semiconductor region is made of n-type AlInGaAs-based compound semiconductor highly doped for example with Si or Te. For example, the tunnel junction layer 107 has a thickness about in the range from 30 nm to 70 nm (e.g., 50 nm).

### (Active Layer)

The active layer 105 has a multiple quantum well structure (MQW structure) including a barrier layer and a quantum well layer for example made of AlGaInAs-based compound semiconductor. The active layer 105 may have a single quantum well structure (QW structure) including for example a barrier layer and a quantum well layer made of AlGaInAs-based compound semiconductor. The region of the active layer 105 corresponding to the tunnel junction layer 107 is an emission region. The light emission region of the active layer 105 is also a heat-generating part.

### (Second Reflector)

The reflector 110 as the second reflector is for example a dielectric multilayer film reflector (dielectric DBR) having multiple kinds (e.g., two kinds) of refractive index layers (dielectric layers) with different refractive indexes alternately stacked on each other with an optical thickness of ¼ of the oscillation wavelength λ(λ/4). For example, the dielectric multilayer film reflector as the reflector 110 has high refractive index layers (such as a Ta₂O₅ layer) and low refractive index layers (such as a SiO₂ layer) alternately stacked on each other. The reflector 110 as the second reflector has a slightly lower reflectance than the first reflector which includes the semiconductor multilayer film reflector 103 and the metal film 102. In other words, the reflector 110 as the second reflector is the reflector on the emission side. Note that the reflector 110 may be a multilayer film reflector such as a semiconductor multilayer film reflector instead of the dielectric multilayer film reflector.

### (Anode Electrode)

An anode electrode 109 is for example provided on the embedding layer 108 in a frame shape (such as an annular shape) to surround the reflector 110. The anode electrode 109 is for example made of Au/Ni/AuGe or Au/Pt/Ti. The anode electrode 109 is for example electrically connected to the anode (positive electrode) of a laser driver.

### (First Reflector: Semiconductor Multilayer Film Reflector and Metal Film)

The first reflector is a hybrid mirror including the semiconductor multilayer film reflector 103 and the metal film 102.

In the semiconductor multilayer film reflector 103 (semiconductor DBR), the amorphous layers 103a and the mixed crystal layers 103b are for example alternately stacked. In other words, the semiconductor multilayer film reflector 103 has pairs of amorphous layers 103a and mixed crystal layers 103b. The number of the pairs is preferably 10 or more and 50 or less, more preferably 15 or more and 25 or less. The optical thicknesses of the amorphous layer 103a and the mixed crystal layer 103b are for example both ¼ of the oscillation wavelength λ(λ/4). The semiconductor multilayer film reflector 103 may be either doped or non-doped.

The amorphous layer 103a is for example an InP layer, and the mixed crystal layer 103b is for example an AlGaInAs layer. The thermal conductivity of InP, which is amorphous, is about 10 times that of AlGaInAs, which is quaternary amorphous. In other words, the semiconductor multilayer film reflector 103 has better heat dissipation than the semiconductor multilayer film reflector with a pair of mixed crystal layers (e.g., AlGaInAs/AlGaInAs).

The furthermost layer (bottom layer) from the active layer 105 of the semiconductor multilayer film reflector 103 is preferably an InP layer, which is an amorphous layer 103a. In other words, the back surface BS of the semiconductor multilayer film reflector 103 is preferably one surface of a single amorphous layer 103a.

The number of pairs in the semiconductor multilayer film reflector 103 is set to be fewer (e.g., half or less) than when a single semiconductor multilayer film reflector is used for the first reflector (a normal case). In other words, the semiconductor multilayer film reflector 103 is thinner than the normal case.

The metal film 102 is for example provided flat on the back surface BS of the semiconductor multilayer film reflector 103 (see FIGS. 1A and 1B). The white dashed line circle in FIG. 1B indicates the area corresponding to the light emission region of the metal film 102.

The metal film 102 and the semiconductor multilayer film reflector 103 constitute the first reflector and the cathode electrode and also constitute a heat dissipation area that dissipates heat generated in the light emission region of the active layer 105 and the tunnel junction layer 107 and transmitted through the semiconductor multilayer film reflector 103 to the outside. The white arrows in FIG. 1A indicate main heat transfer. As can be seen, heat mainly moves radially from the heat-generating part to the metal film 102. The metal film 102 as the cathode electrode is for example electrically connected to the cathode (negative electrode) of the laser driver.

The cathode electrode may be provided separately from the metal film 102. In this case, the anode electrode and the cathode electrode may be arranged in positions (upper and lower sides) to sandwich the active layer therebetween or on the same plane (intracavity).

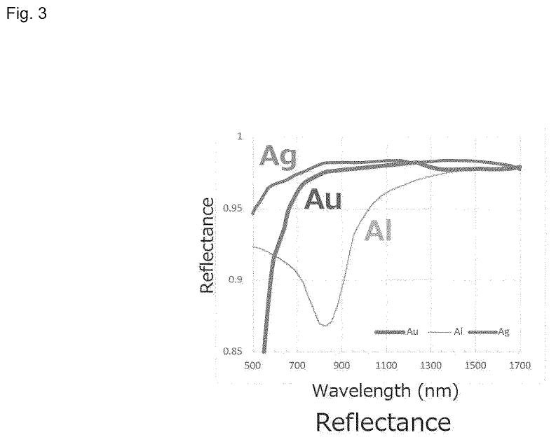

The metal film 102 is for example preferably made of Au, Ag, or Al. As can be understood from FIG. 3, Au, Ag, and Al can stably provide high reflectance over a wide wavelength band, especially on the long wavelength side.

The characteristics of the first reflector which is a hybrid mirror will be described here. Normally a metal film has some optical absorption and cannot be used as a reflector for VCSELs by itself. However, when the metal film is combined with a DBR, a good reflectance characteristic can be achieved while reducing the number of DBR pairs.

When actually comparing the results of measuring the reflectance of 50 pairs of DBRs only (the former) and the reflectance of 25 pairs of DBRs combined with a metal film (the latter), it has been found that in the latter, the reflectance difference due to the difference in the number of DBR pairs can be compensated for by the reflectance of the metal film, and high reflectance equivalent to that of the former can be obtained.

It should be noted here that the combination of the InP-based semiconductor DBR and the metal film increases the overall reflectance and the effective stopband width. While dielectric DBRs and AlGaAs-based DBRs can increase the stopband width, InP-based DBRs (for example with InP/AlGaInAs pairs) have a narrower stopband width and require a larger number of DBR pairs because there cannot be inherently large refractive index difference between the materials. In other words, to reduce the number of pairs of InP-based semiconductor DBRs and improve the heat dissipation by attaching a metal film to the InP-based semiconductor DBRs may be a major advantage for InP VCSELs.

As a result of determining the relation between Gth (a numerical value that quantitatively indicates a reflectance characteristic, with smaller values indicating a better reflectance characteristic) and the number of pairs of InP-based DBRs in InP-based VCSELs, it has been found that the presence of a metal film of a metal with a high reflectance such as Au on the back surface of an InP-based DBR can significantly reduce the number of pairs of DBRs and improve the heat dissipation. In particular, it has been found that both the heat dissipation and reflectance characteristic can be improved by attaching for example a metal film to a DBR with InP/AlGaInAs pairs.

Since the surface of the InP-based semiconductor DBR with a metal film cannot emit light, the first reflector cannot be used as a reflector on the output side. However, the stop bandwidth may become narrower if the InP-based DBR is used on the output side by itself. Therefore, it is preferable to use a dielectric DBR with a sufficient material refractive index difference and a wide stopband width for the second reflector, which is the DBR on the emission side. By using a dielectric DBR on the output side, a device with a good optical characteristic and high yields can be realized.

### <<Operation of Surface Emitting Laser>>

In the surface emitting laser 10-1, current allowed to flow in from the anode side of the laser driver through the anode electrode 109 is narrowed by the BTJ and injected through the second cladding layer 106 into the active layer 105. At the time, the active layer 105 emits light, and the light travels back and forth between the first and second reflectors while being narrowed by the BTJ and amplified by the active layer 105, and when the oscillation condition is met, the light is emitted as laser light from the side of the first reflector 110. The current injected into the active layer 105 is passed to the cathode side of the laser driver through the first cladding layer 104, the semiconductor multilayer film reflector 103, and the cathode electrode (metal film 102) in that order.

Most of the heat generated in the tunnel junction layer 107 and the active layer 105 when the surface emitting laser 10-1 is driven reaches the metal film 102 through the semiconductor multilayer film reflector 103 relatively quickly and is emitted from the side of the metal film 102 and the substrate 101 to the outside. The remainder of the generated heat is emitted externally from sides of the semiconductor multilayer film reflector 103 (mainly from sides of each InP layer).

### <<Method of Manufacturing Surface Emitting Laser>>

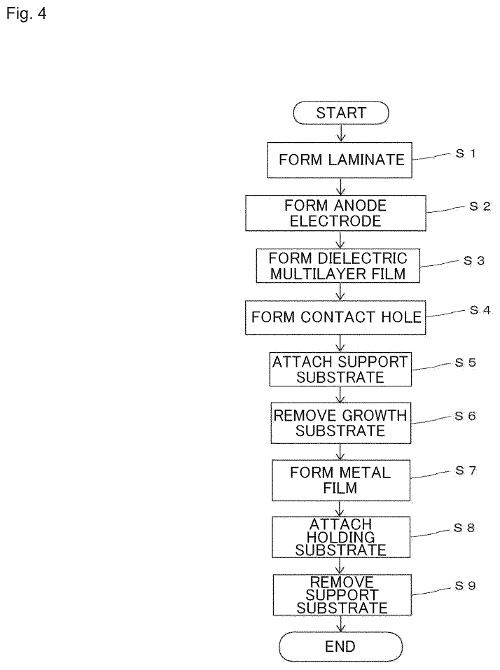

Hereinafter, a method for manufacturing the surface emitting laser 10-1 will be described with reference to the flowchart (steps S1 to S9) in FIG. 4 and FIGS. 5A to 9. Here, as an example, a plurality of surface emitting lasers 10-1 are simultaneously produced on a single wafer that serves as the base material of the substrate 101 by a semiconductor manufacturing method using a semiconductor manufacturing device. Then, the plurality of integrally formed surface emitting lasers 10-1 are separated to obtain the multiple surface emitting lasers 10-1 in a chip form (surface emitting laser chip). As an example, the surface emitting laser 10-1 is produced by a semiconductor manufacturing device according to the procedure in the flowchart in FIG. 4.

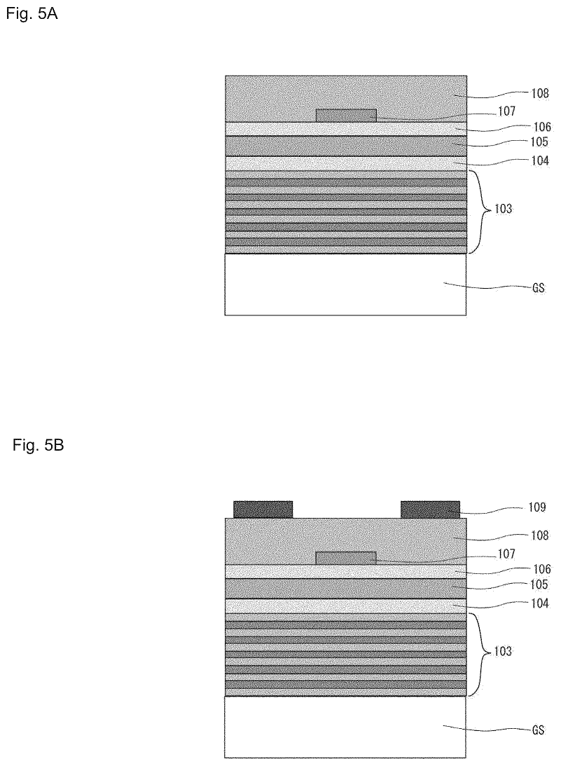

In the first step S1, a laminate is produced (see FIG. 5A). Specifically as an example, an etch stop layer (such as an InGaAsP layer, and an AlGaInAs layer), the semiconductor multilayer film reflector 103, the first cladding layer 104, the active layer 105, the second cladding layer 106, the tunnel junction layer 107, and the embedding layer 108 are stacked on each other in this order on a growth substrate GS (such as an InP substrate) in a growth chamber by metal organic chemical vapor deposition (MOCVD) or molecular beam epitaxy (MBE) to form the laminate.

In the following step S2, the anode electrode 109 is formed (see FIG. 5B). More specifically a frame shaped (e.g., an annular shape) anode electrode 109 that surrounds a region corresponding to the tunnel junction layer 107 is formed on the embedding layer 108 for example by lifting off.

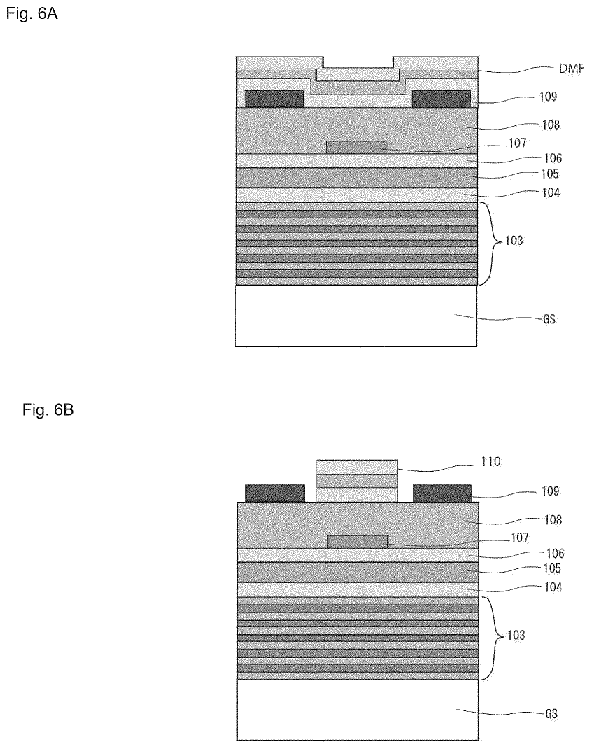

In the following step S3, a dielectric multilayer film DMF is deposited (see FIG. 6A). Specifically the dielectric multilayer film DMF, the material of the reflector 110, is deposited on the entire surface of the laminate on which the anode electrode 109 is formed.

In the following step S4, a contact hole is formed (see FIG. 6B). Specifically the part of the dielectric multilayer film DMF that covers the anode electrode 109 is removed by dry etching to form a contact hole to expose the anode electrode 109. As a result, the reflector 110 is formed.

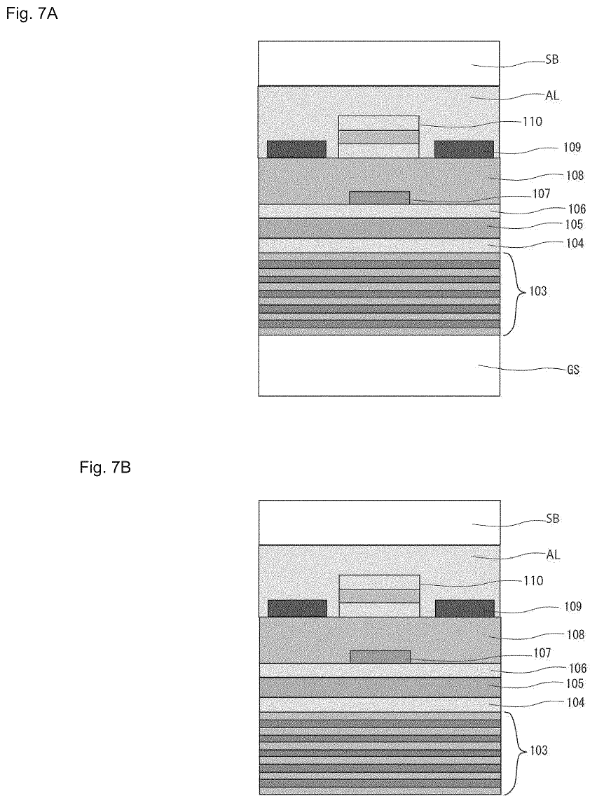

In the following step S5, a support substrate SB (temporarily attached substrate) is attached (see FIG. 7A). Specifically the support substrate SB (such as a sapphire substrate) is attached on the surface of the laminate on the side of the anode electrode 109 and the reflector 110 through an adhesive layer AL for example made of resin.

In the following step S6, the growth substrate GS is removed (see FIG. 7B). Specifically the back surface of the growth substrate GS (see FIG. 7A) is roughly ground with a back grinder, and the remaining part is removed by wet etching. During the process, etching can be stopped at the etch stop layer, and only the growth substrate GS can be removed. The etch stop layer is then removed by another kind of etchant to expose the back surface of the semiconductor multilayer film reflector 103 (e.g., one side of the InP layer).

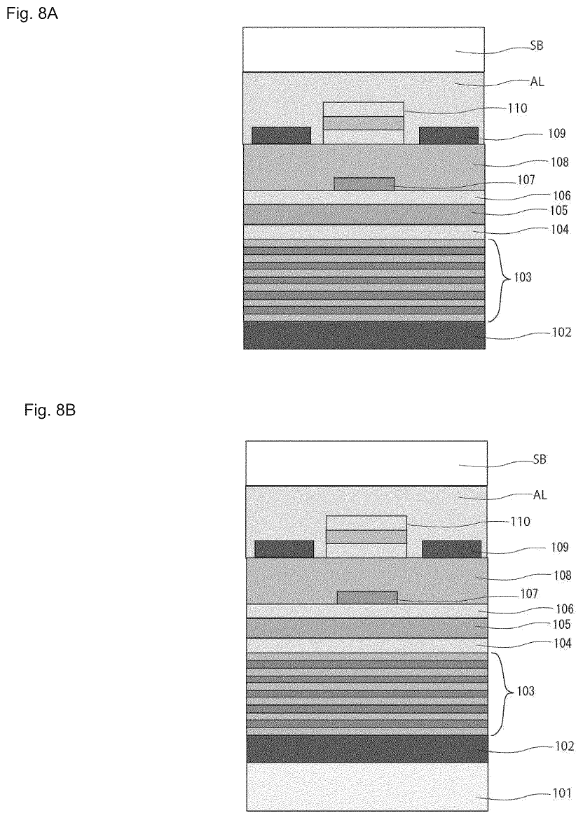

In the following step S7, the metal film 102 is formed (see FIG. 8A). Specifically to start with, a thin Au film is for example formed on the back surface of the semiconductor multilayer film reflector 103 by vapor deposition, and the thin Au film as a seed is plated with Au and formed into a thick film. Then, the thick Au film is polished and planarized using a CMP (Chemical Mechanical Polishing) device.

In the following step S8, the substrate 101 is attached as a holding substrate (see FIG. 8B). Specifically the substrate 101 is attached to the metal film 102 through for example solder or Ag paste (conductive adhesive). The method for bonding the metal 102 to the substrate 101 is not limited to the above method.

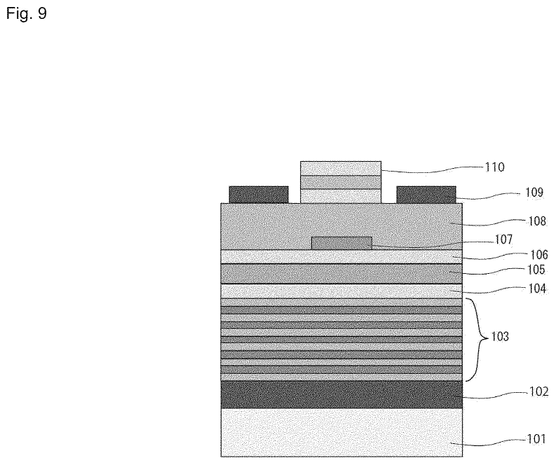

In the final step S9, the support substrate SB is removed (see FIG. 9). Specifically the adhesive layer AL is dissolved by heating, and the support substrate SB and the adhesive layer AL are removed. Thereafter, processing such as annealing is performed, and the resulting structure is separated by dicing into a plurality of surface emitting lasers 10-1 (surface emitting laser chips) in chip form.

### <<Advantageous Effects of Surface Emitting Laser>>

The surface emitting laser 10-1 according to Example 1 of the embodiment of the present technology includes the semiconductor multilayer film reflector 103, the reflector 110, the active layer 105 provided between the semiconductor multilayer film reflector 103 and the reflector 110, and the metal film 102 provided on the back surface BS which is the surface of the semiconductor multilayer film reflector 103 on the side opposite to the active layer side 105.

In this case, heat generated in the active layer 105 is discharged to the outside through the semiconductor multilayer film reflector 103 and the metal film 102 in this order.

As a result, the surface emitting laser 10-1 can be provided as a surface emitting laser that allows for improved heat dissipation.

In the semiconductor multilayer film reflector 103, the amorphous layers 103a and the mixed crystal layers 103b are alternately stacked on each other. This allows for improved heat dissipation as compared to the semiconductor multilayer film reflector including mixed crystal layers only.

The amorphous layer 103a is an InP layer and the mixed crystal layer 103b is an AlGaInAs layer. In this way improved heat dissipation is allowed in a semiconductor multilayer film reflector for a InP-based surface emitting laser with an oscillation wavelength on the long side (for example at least 900 nm).

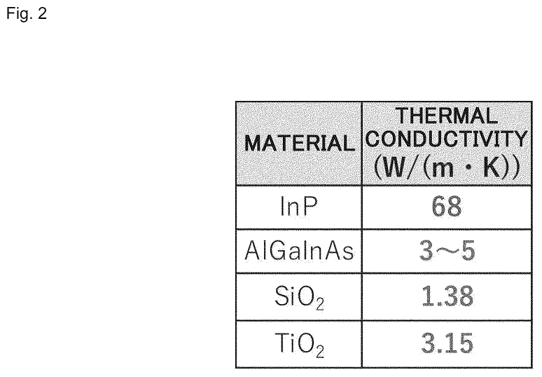

To add to the above, there are mixed-crystal materials such as AlGaInAs and InGaAsP that make up InP-based semiconductor DBRs. However, the thermal conductivity of the mixed-crystal materials is one order of magnitude lower than that of normal InP-based materials (non-mixed-crystalline materials) (see FIG. 2). In other words, a DBR having only mixed-crystal materials repeatedly deposited in multiple layers includes materials mostly with low thermal conductivity heat generated in the current constriction zone and the active layer is difficult to dissipate to the outside. In the surface emitting laser 10-1, the first reflector includes the semiconductor multilayer film reflector 103, the material of which is InP/AlGaInAs having high thermal conductivity and a small number of pairs and the metal film 102, so that both high reflectance and high heat dissipation both can be achieved. The improvement of heat dissipation means that the temperature characteristic of the InP-based surface emitting laser, the temperature-dependent characteristic fluctuation of which is particularly disadvantageous, can be improved, leading to higher output power.

The reflectance can be increased by increasing the number of pairs of DBRs. This is the same for a InP-based semiconductor DBR with a small Δn (refractive index difference between pairs). However, a material with a small Δn does not allow the stopband width to be increased. Since the InP-based material has a narrow stopband width, a variation in film thickness during crystal growth can change the stopband, resulting in a significant decrease in yield. In particular, the problem becomes more serious for larger substrates. Also, when the temperature changes during the operation of the laser and the stopband width is narrow, the emission characteristic may fluctuate greatly according to the temperature. In other words, a large stopband width is a very significant advantage for InP-based VCSELs. The combination of an InP-based DBR and a metal film makes it possible to increase the effective stopband width. This can effectively improve the temperature characteristic and yield.

In the surface emitting laser 10-1, the effective stop bandwidth can be increased, which can reduce the yield decrease attributable to variations in the DBR thickness. In addition, when for example metal or Ag paste is used for bonding, the generation of voids can be suppressed for example compared to direct epitaxial bonding, which therefore improves the yield. In addition, the cost can be reduced because an inexpensive substrate such as a Si substrate and a glass substrate can be used as the holding substrate as compared to the case of directly bonding a semiconductor structure of an AlGaAs-based semiconductor DBR and a semiconductor substrate to the semiconductor multilayer film reflector 103.

The back surface BS of the semiconductor multilayer film reflector 103 is one surface of one amorphous layer 103a. This can improve the thermal conductivity between the semiconductor multilayer film reflector 103 and the metal film 102, so that the heat dissipation can be further improved.

The metal film 102 is preferably made of Au, Ag, or Al. This is advantageous in in that high reflectance can be obtained in the surface emitting laser 10-1 having an oscillation wavelength on the long wavelength side (for example at least 900 nm).

The reflector 110 is a dielectric multilayer film reflector. This makes it possible to increase the stopband width of the reflector 110 and to obtain high reflectance with a small number of pairs.

The embedding layer 108 is for example made of an InP layer. In this case, in easily migrates and therefore helps improve the flatness of the embedding layer 108 during its growth. This allows for a good junction interface between the embedding layer 108 and the reflector 110. Meanwhile, if a mixed-crystal material is used for the embedding layer 108, composition mismatch may occur or difficulty in migration may prevent the flatness from being improved.

As described above, InP, an amorphous material, has higher thermal conductivity than a mixed crystal material. Therefore, the use of InP as the material for the embedding layer 108 can improve the direct heat dissipation to the outside from the embedding layer 108 which embeds the periphery of the tunnel junction layer 107 as the heat-generating part as compared to the case of using for example a mixed crystal material.

### <2. Surface Emitting Laser According to Example 2 of the Embodiment of Present Technology>

Hereinafter, a surface emitting laser according to Example 2 of the embodiment of the present technology will be described.

### <<Configuration of Surface Emitting Laser>>

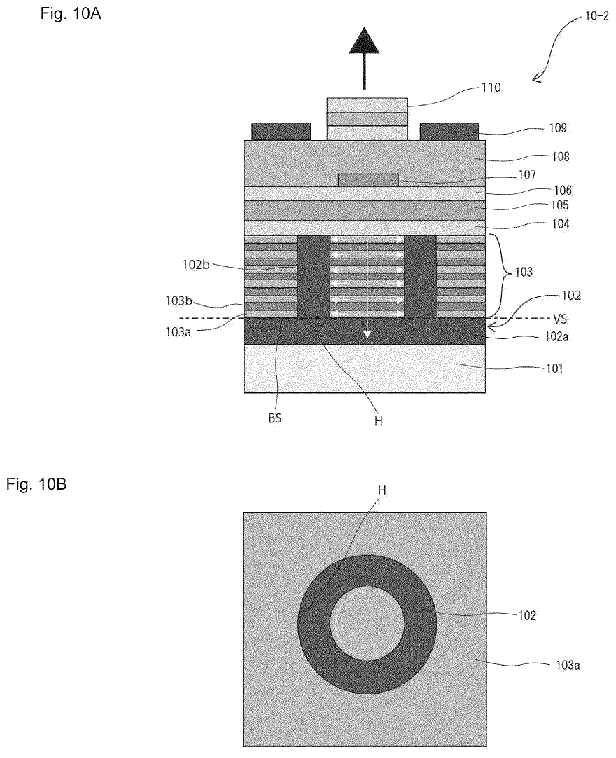

FIG. 10A is a cross-sectional view of a surface emitting laser 10-2 according to Example 2 of the embodiment of the present technology. FIG. 10B is a plan view of a semiconductor multilayer film reflector 103 in which a part of the metal film 102 of the surface emitting laser 10-2 according to example 2 of the embodiment of the present technology is provided.

As shown in FIGS. 10A and 10B, the surface emitting laser 10-2 has the same configuration as that of the surface emitting laser 10-1 according to Example 1 except that the metal film 102 has a first part 102a as a part on a virtual surface VS including the back surface BS of the semiconductor multilayer film reflector 103 on the opposite side to the side of the active layer 105, and a second part 102b as a further part provided inside of the semiconductor multilayer film reflector 103.

More specifically in the surface emitting laser 10-2, the metal film 102 has the first part 102a provided at the back surface BS of the semiconductor multilayer film reflector 103 and the second part 102b provided inside of the semiconductor multilayer film reflector 103.

The first part 102a is for example provided flat on the back surface BS of the semiconductor multilayer film reflector 103. The second part 102b is for example provided in a tubular shape to surround a region of the semiconductor multilayer film reflector 103 corresponding to a light emission region of the active layer 105. The second part 102b is in contact with a side surface (side surfaces of InP layer and AlGaInAs layer) of the semiconductor multilayer film reflector 103.

More specifically a hole H is provided at the back surface of the semiconductor multilayer film reflector 103, and the second part 102b as the further part of metal film 102 is fitted into the hole H. The second part 102b is in contact with the inner surface up the hole H (the side surfaces of the InP layer and AlGaInAs layer).

The hole H is for example provided in a tubular shape extending in the thickness-wise direction (stacking direction) of the semiconductor multilayer film reflector 103. The hole H is provided to penetrate the semiconductor multilayer film reflector 103.

The hole H is provided around a region of the semiconductor multilayer film reflector 103 corresponding to the light emission region of the active layer 105. More specifically at least one hole H (one for example) is provided to surround the region of the semiconductor multilayer film reflector 103 corresponding to the light emission region of the active layer 105.

Meanwhile, in the semiconductor multilayer film reflector 103, the InP layer with high thermal conductivity and the AlGaInAs layer with poor heat dissipation (with low thermal conductivity) are stacked on each other. More specifically heat is less easily transmitted in the vertical direction (up-down direction) and more easily transmitted in the horizontal direction in the semiconductor multilayer film reflector 103. In order to make most of the property in the surface emitting laser 10-2, the region of the semiconductor multilayer film reflector 103 that surrounds the region corresponding to the light emission region is replaced with the second part 102b as the further part of the metal film 102 having high heat dissipation (high thermal conductivity). In this structure, since the side surfaces of the InP layers of the semiconductor multilayer film reflector 103 are in contact with the second part 102b of the metal film 102, heat can be efficiently transmitted from the side surfaces to the metal film 102. The results of simulations regarding heat dissipation conducted on both the AlGaInAs/AlGaInAs semiconductor DBR and the InP/AlGaInAs semiconductor DBR by applying the structure of the surface emitting laser 10-2, the InP/AlGaInAs semiconductor DBR has significantly improved heat dissipation with the structure of the surface emitting laser 10-2.

The surface emitting laser 10-2 operates similarly to the surface emitting laser 10-1 according to Example 1. Here, the white arrows in FIG. 10 indicate the flow of heat. During the operation of the surface emitting laser 10-2, most of heat generated at the heat generating part (the active layer 105 and the tunnel junction layer 107) flows transversely to the second part 102b of the metal film 102 in the InP layers of the semiconductor multilayer film reflector 103, and then vertically to the first part 102a of the metal film 102 along the second part 102b. The remainder of the heat generated at the heat generating part flows vertically from the heat generating part to the first part 102a across the layers of the semiconductor multilayer film reflector 103. The heat transmitted to the first part 102a is discharged to the outside through the side surface of the first part 102a and the substrate 101.

### <<Method for Manufacturing Surface Emitting Laser>>

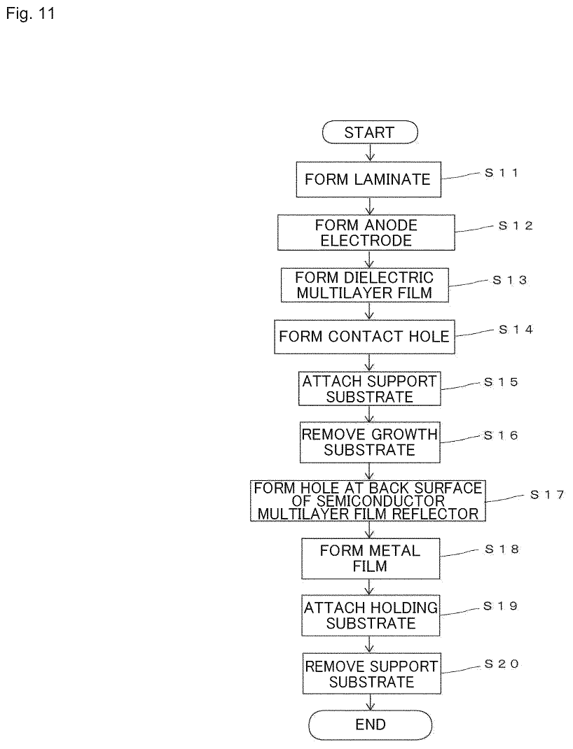

Hereinafter, a method for manufacturing the surface emitting laser 10-2 will be described with reference to the flowchart (steps S11 to S20) in FIG. 11, FIGS. 5A to 7B, and FIGS. 12A to 13B. Here, a plurality of surface emitting lasers 10-2 are produced simultaneously on a single wafer as a base material for the substrate 101 according to a semiconductor manufacturing method using a semiconductor manufacturing device by way of illustration. Then, the multiple surface emitting laser 10-2 formed integrally are separated into multiple chip-shaped surface emitting lasers (surface emitting laser chips) 10-2 are obtained. The surface emitting laser 10-2 are manufactured for example according to the procedure in the flowchart in FIG. 11.

In the first step S11, a laminate is produced (see FIG. 5A). More specifically an etch-stop layer (such as an InGaAsP layer and an AlGaInAs layer), a semiconductor multilayer film reflector 103, a first cladding layer 104, an active layer 105, a second cladding layer 106, a tunnel junction layer 107, and an embedding layer 108 are produced in this order on a growth substrate GS (such as an InP substrate) in a growth chamber by metal organic chemical vapor deposition (MOCVD) or molecular-beam epitaxy (MBE), to produce a laminate by way of illustration.

In the following step S12, an anode electrode 109 is formed (see FIG. 5B). More specifically the frame-shaped (such as an annular shape) anode electrode 109 surrounding the region of the embedding layer 108 corresponding to the tunnel junction layer 107 is formed in the embedding layer 108 for example by lifting off.

In the following step S13, a dielectric multilayer film DMF is formed (see FIG. 6A). More specifically the dielectric multilayer film DMF, a material for a reflector 110 is formed entirely over the laminate in which the anode electrode 109 is formed.

In the following step S14, a contact hole is formed (see FIG. 6B). More specifically the part that covers the anode electrode 109 of the dielectric multilayer film DMF is removed by dry etching to form a contact hole, through which the anode electrode 109 is exposed. As a result, the reflector 110 is formed.

In the following step S15, a support substrate SB (temporarily attached substrate) is attached (see FIG. 7A). More specifically the support substrate SB is attached on the surface of the laminate on the side of the anode electrode 109 and then the reflector 110 for example through an adhesive layer AL.

In the following step S16, the growth substrate GS is removed (see FIG. 7B). More specifically the back surface of the growth substrate GS (see FIG. 7A) is roughly ground using a back grinder, and the remaining part is removed by wet etching. During the process, the etching can be stopped by an etch stop layer, so that only the growth substrate GS can be removed. Then, the etch stop layer is removed by another kind of etchant to expose the back surface (such as a surface of the InP layer) of the semiconductor multilayer film reflector 103.

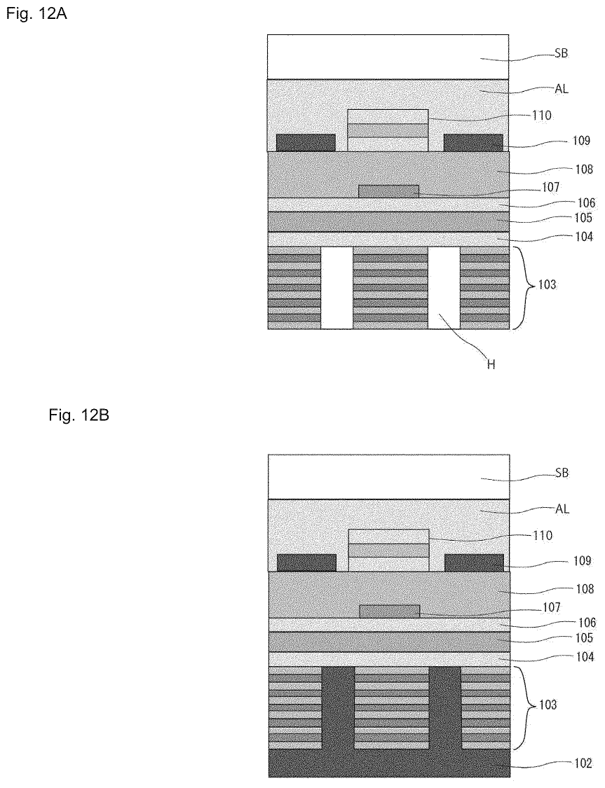

In the following step S17, a hole H is formed at the back surface of the semiconductor multilayer film reflector 103 (see FIG. 12A). More specifically a resist pattern to cover the part of the semiconductor multilayer film reflector 103 other than the part for forming the back surface hole H is formed, and the hole H is formed by etching the semiconductor multilayer film reflector 103 for example by dry etching using the resist pattern as a mask. The etching is performed to such a depth that the first cladding layer 104 is exposed. As a result, the hole H that penetrates the semiconductor multilayer film reflector 103 is formed.

In the following step S18, a metal film 102 is formed (see FIG. 12B). More specifically a thin Au film for example is formed at the back surface of the semiconductor multilayer film reflector 103 and in the hole H by vapor deposition to start with, and the thin Au film as a seed is further Au plated and formed into a thick film, so that the hole H is filled with a part of the Au thickened film and a further part of the Au thickened film is formed flat entirely on the back surface of the semiconductor multilayer film reflector 103. Then, the further part of the Au thickened film is planarized by polishing using a CMP device.

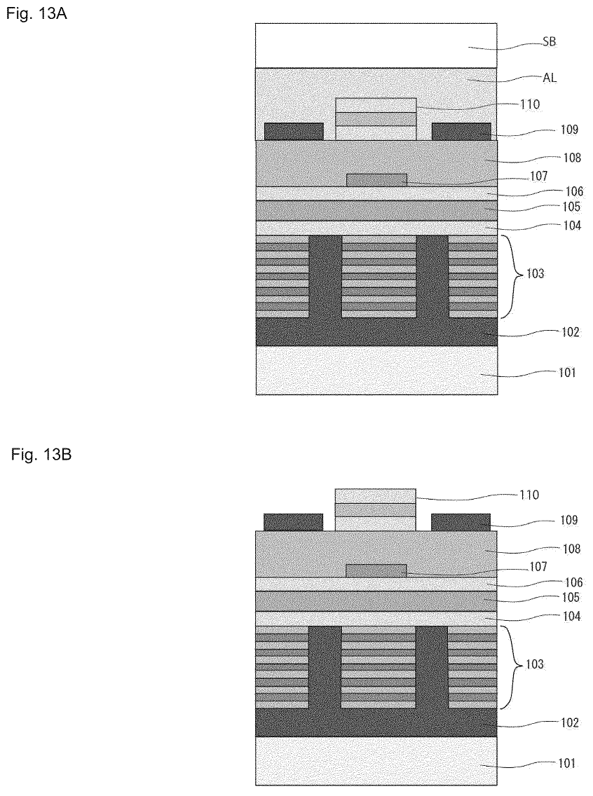

In the following step S19, the substrate 101 as a holding substrate is attached (see FIG. 13A). More specifically, the substrate 101 is attached to the metal film 102 for example through Ag paste (a conductive adhesive).

In the final step S20, the support substrate SB is removed (see FIG. 13B). More specifically the adhesive layer AL is dissolved by heating, and the support substrate SB and the adhesive layer AL are removed. Then, processing such as annealing is performed, and the resulting structure is separated by dicing into a plurality of chip-shaped surface emitting lasers 10-1 (surface emitting laser chips).

### <<Advantageous Effects of Surface Emitting Laser>>

In the surface emitting laser 10-2, the metal film 102 has one part 102a provided on the side opposite to the side of the active layer 105 of the virtual surface VS including the back surface BS of the semiconductor multilayer film reflector 103 and the second part 102b provided as the further part inside of the semiconductor multilayer film reflector 103. This can significantly improve the heat dissipation.

The second part 102b of the metal film 102 provided in the semiconductor multilayer film reflector 103 is in contact with the side surface of the semiconductor multilayer film reflector 103. This can significantly improve the heat dissipation.

The hole H is provided at the back surface BS of the semiconductor multilayer film reflector 103, and the second part 102b of the metal film 102 is fitted into the hole H. This can significantly improve the heat dissipation with a simple structure.

The second part 102b of the metal film 102 is in contact with the inside surface of the hole H. This can significantly improve the heat dissipation.

The hole H penetrates the semiconductor multilayer film reflector 103. In this way the second part 102b of the metal film 102 can be extended to the vicinity of the active layer 105 as the heat generating part, so that the heat dissipation can be further improved.

The hole H is provided around the region of the semiconductor multilayer film reflector 103 corresponding to the light emission region of the active layer 105.

In this way, the second part 102b of the metal film 102 can be provided in a location that does not affect laser oscillation.

At least one hole H (one for example) is provided to surround the region of the semiconductor multilayer film reflector 103. In this way, heat discharged for example from the active layer 105 as the heat generating part can be transmitted to the side of the back surface BS of the semiconductor multilayer film reflector 103 efficiently through the second part 102b of the metal film 102.

### <3. Surface Emitting Laser According to Example 3 of the Embodiment of Present Technology>

Hereinafter, a surface emitting laser according to Example 3 of the embodiment of the present technology will be described.

### <<Configuration of Surface Emitting Laser>>

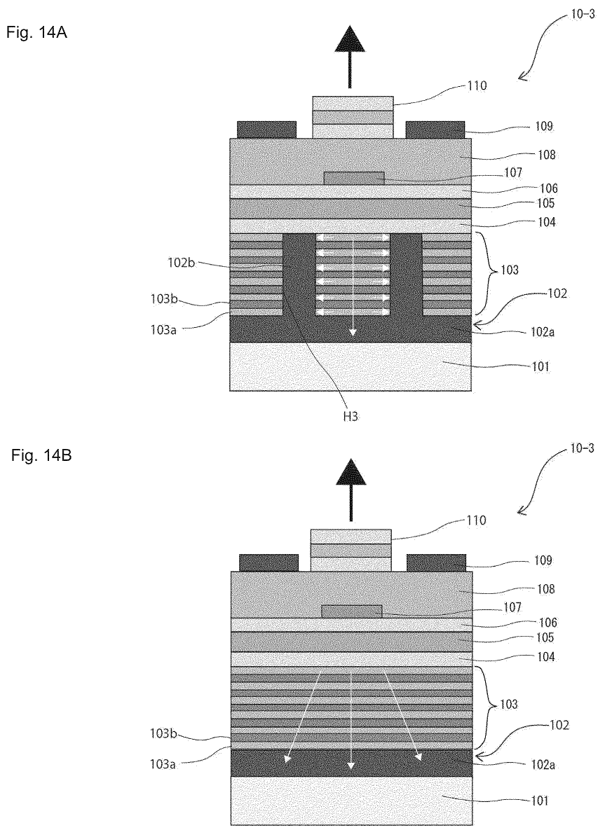

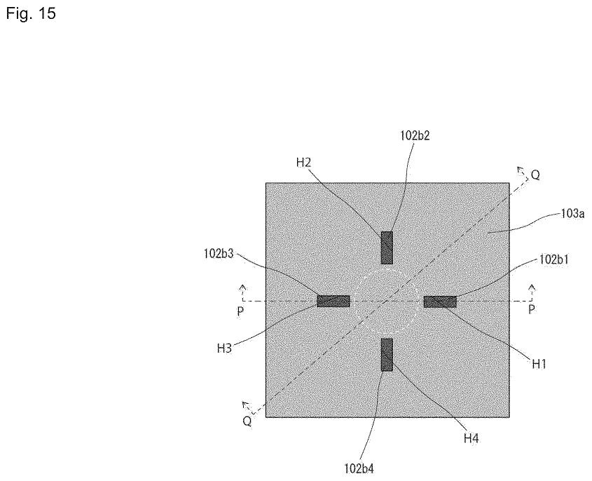

FIGS. 14A and 14B are cross-sectional views (part 1 and part 2) of a surface emitting laser 10-3 according to Example 3 of the embodiment of the present technology. FIG. 15 is a plan view of a semiconductor multilayer film reflector 103 in which a part of the metal film 102 of the surface emitting laser 10-3 according to Example 3 of the embodiment of the present technology is provided. More specifically, FIG. 14A is a cross-sectional view of the surface emitting laser 10-3 taken along a plane including a section along line P-P in FIG. 15. FIG. 14B is a cross-sectional view of the surface emitting laser 10-3 taken along a plane including a section along line Q-Q in FIG. 15.

As shown in FIGS. 14A, 14B, and 15, the surface emitting laser 10-3 has the same configuration as that of the surface emitting laser 10-2 according to Example 2 except that a plurality of (for example four) holes H are provided to surround the region of the semiconductor multilayer film reflector 103 corresponding to the light emission region of the active layer 105.

The plurality of (for example four) holes H (such as H1 to H4) are provided to surround the four sides of the region of the semiconductor multilayer film reflector 103 corresponding to the light emission region. The holes H each have a rectangular cross section by way of illustration. The total volume of the plurality of holes H1 to H4 for example is smaller than the volume of the hole H of the surface emitting laser 10-2 according to Example 2.

The plurality of holes H (H1 to H4) are individually provided with a plurality of second parts 102b (102b1 to 102b4) of the metal films 102.

The surface emitting laser 10-3 can be manufactured by a manufacturing method substantially the same as the method for manufacturing the surface emitting laser 10-2 according to Example 2.

In the surface emitting laser 10-3, reduction in the mechanical strength of the semiconductor multilayer film reflector 103 can be restrained as compared to the surface emitting laser 10-2 according to Example 2 while the heat dissipation is lower since the volume of the metal film in the semiconductor multilayer film reflector 103 is smaller. Therefore, the surface emitting laser 10-3 is effectively used when more robustness is required.

### <4. Surface Emitting Laser According to Example 4 of the Embodiment of Present Technology>

Hereinafter, a surface emitting laser according to Example 4 of the embodiment of the present technology will be described.

### <<Configuration of Surface Emitting Laser>>

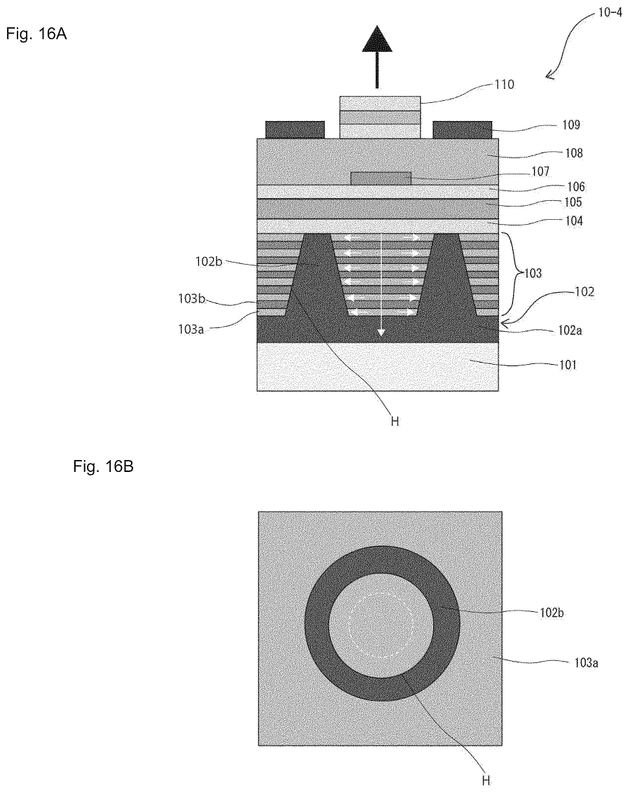

FIG. 16A is a cross-sectional view of a surface emitting laser 10-4 according to Example 4 of the embodiment of the present technology. FIG. 16B is a plan view of a semiconductor multilayer film reflector in which a part of the metal film 102 of the surface emitting laser 10-4 according to Example 4 of the embodiment of the present technology is provided.

As shown in FIGS. 16A and 16B, the surface emitting laser 10-4 has the same configuration as that of the surface emitting laser 10-2 according to Example 2 except that at least a part of the hole H (e.g., the entire hole H) is tapered in side view (the width of the hole becomes wider in a direction apart from the active layer 105).

The surface emitting laser 10-4 can be manufactured by a method substantially the same as the method for manufacturing the surface emitting laser 10-2 according to Example 2.

The surface emitting laser 10-4 can exhibit the same advantageous effect as the surface emitting laser 10-2 according to Example 2, and since the hole H is tapered in side view, the contact area between the inner side surface of the semiconductor multilayer film reflector 103 (inner surface of the hole H) and the second part 102b of the metal film 102 can be increased, and the thermal conductivity therebetween can be further improved. This also makes it easier to bring the second part 102b of the metal film 102 into better contact with the inner side surface of the semiconductor multilayer film reflector 103 when the metal film 102 is formed.

### <5. Surface Emitting Laser According to Example 5 of the Embodiment of Present Technology>

Hereinafter, a surface emitting laser according to Example 5 of the embodiment of the present technology will be described.

### <<Configuration of Surface Emitting Laser>>

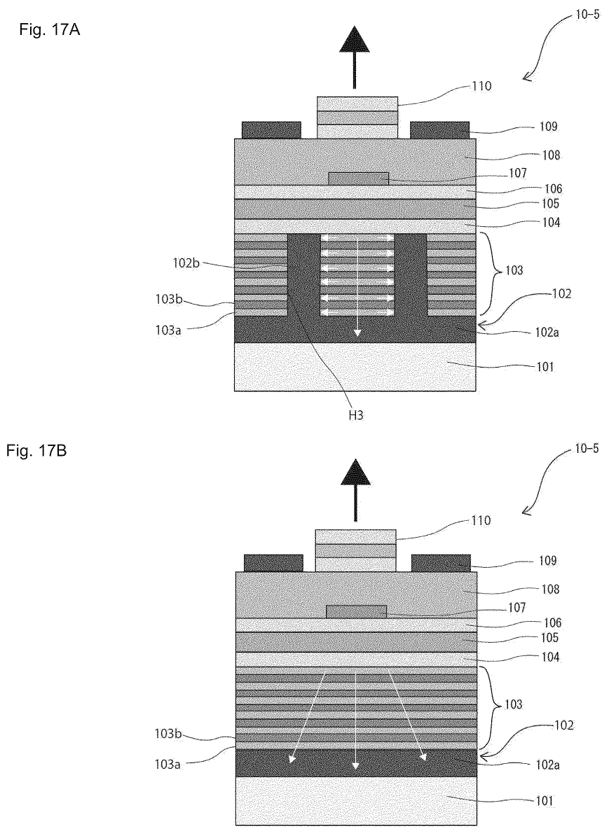

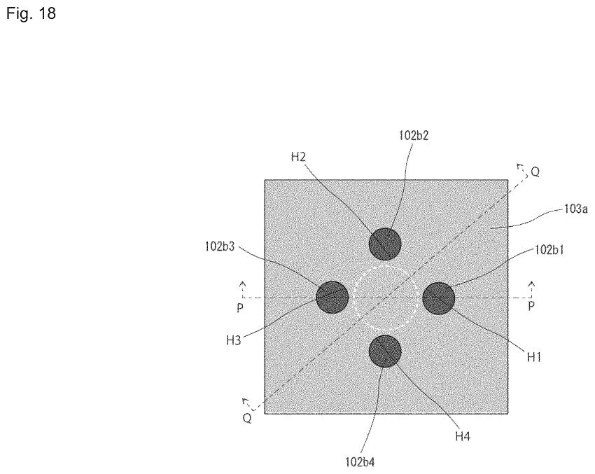

FIGS. 17A and 17B are cross-sectional views (part 1 and part 2) of a surface emitting laser 10-5 according to Example 5 of the embodiment of the present technology. FIG. 18 is a plan view of the semiconductor multilayer film reflector 103 in which a part of the metal film 102 of the surface emitting laser 10-5 according to Example 5 of the embodiment of the present technology is provided.

More particularly FIG. 17A is a cross-sectional view of the surface emitting laser 10-5 taken along a plane including a section along line P-P in FIG. 18. FIG. 17B is a cross-sectional view of the surface emitting laser 10-5 taken along a plane including a section along line Q-Q in FIG. 18.

The surface emitting laser 10-5 has the same configuration as that of the surface emitting laser 10-3 according to Example 3 except that each hole H and the second part 102b of the metal film 102 provided in the hole H have a different cross-sectional shape as shown in FIGS. 17A, 17B and 18.

In the surface emitting laser 10-5, the cross-sectional shape of each hole H and the second part 102b provided in the hole H is substantially circular.

The surface emitting laser 10-5 can be manufactured by a method substantially the same as the method for manufacturing the surface emitting laser 10-2 according to Example 2.

The surface emitting laser 10-5 exhibits the same advantageous effect as the surface emitting laser 10-2 according to Example 2, and since the hole H has no edges or other areas which make it difficult for the metal film to adhere to, the metal film can be deposited securely in contact with the inner surface of the hole H.

The cross-sectional shape of the hole H and the second part 102b may be any of other shapes such as an ellipse and a polygon.

### <6. Surface Emitting Laser According to Example 6 of the Embodiment of Present Technology>

Hereinafter, a surface emitting laser according to Example 6 of the embodiment of the present technology will be described.

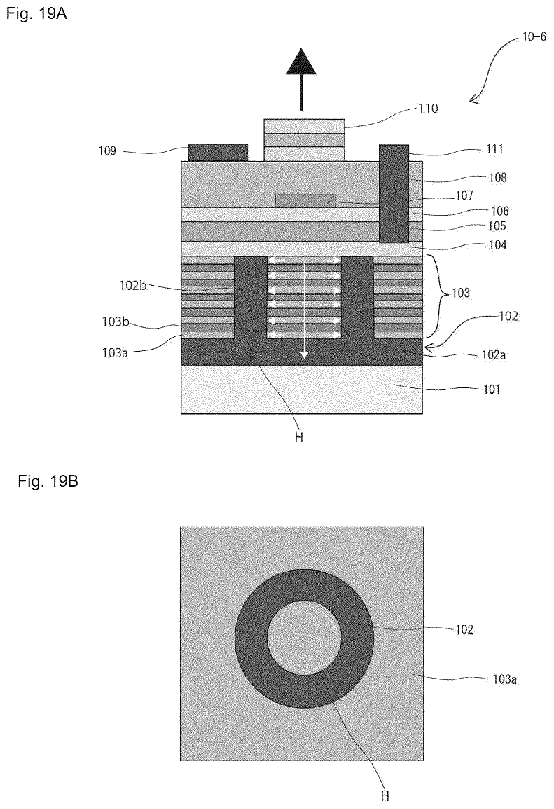

FIG. 19A is a cross-sectional view of the surface emitting laser 10-6 according to Example 6 of the embodiment of the present technology. FIG. 19B is a plan view of a semiconductor multilayer film reflector 103 in which a part of the metal film 102 of the surface emitting laser 10-6 according to Example 6 of the embodiment of the present technology is provided.

As shown in FIGS. 19A and 19B, the surface emitting laser 10-6 as substantially the same configuration as that of the surface emitting laser 10-2 according to Example 2 except that first and second electrodes (anode and cathode electrodes) for injecting current into the active layer 105 are provided on the opposite side to the back surface side of the semiconductor multilayer film reflector 103 or a so-called intracavity structure is provided.

For example, in the surface emitting laser 10-6, a penetrating electrode 111 penetrates the embedding layer 108, the second cladding layer 106, and the active layer 105, and the laser has one end in contact with the first cladding layer 104 and the other end that projects upward from the embedding layer 108.

In other words, in the surface emitting laser 10-6, the penetrating electrode 111 is used as the cathode electrode (second electrode) instead of the metal film 102. Therefore, the penetrating electrode 111 is connected to the cathode (negative electrode) of the laser driver instead of the metal film 102. For example, in the surface emitting laser 10-6, the anode electrode 109 as the first electrode and the penetrating electrode 111 (cathode electrode) as the second electrode are in positions that sandwich the reflector 110 therebetween. The part of the semiconductor multilayer film reflector 103 in contact with the metal film 102 may be undoped and made non-conductive.

The surface emitting laser 10-6 can be manufactured by substantially the same method as the method for manufacturing the surface emitting laser 10-2 according to Example 2.

### <7. Surface Emitting Laser According to Example 7 of the Embodiment of Present Technology>

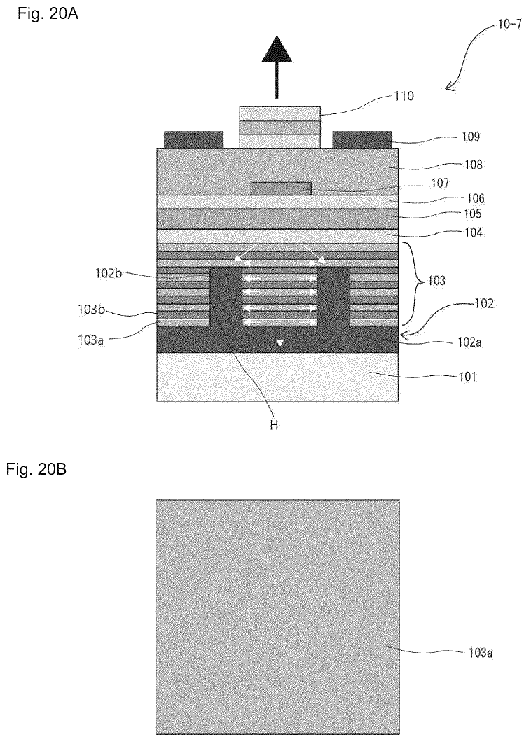

Hereinafter, a surface emitting laser according to Example 7 of the embodiment of the present technology will be described. FIG. 20A is a cross-sectional view of the surface emitting laser 10-7 according to Example 7 of the embodiment of the present technology. FIG. 20B is a plan view of a semiconductor multilayer film reflector in which a part of the metal film 102 of the surface emitting laser 10-7 according to Example 7 of the embodiment of the present technology is provided.

As shown in FIGS. 20A and 20B, the surface emitting laser 10-7 has substantially the same configuration as that of the surface emitting laser 10-2 according to Example 2 except that the hole H does not penetrate the semiconductor multilayer film reflector 103.

The surface emitting laser 10-7 can be manufactured by the same manufacturing method as the method for manufacturing the surface emitting laser 10-2 according to Example 2.

The surface emitting laser 10-7 has heat dissipation inferior to that of the surface emitting laser 10-2 according to Example 2, but the etching time for forming the hole H can be reduced because the depth of the hole H is shallower. Also, since the hole H does not have to penetrate the semiconductor multilayer film reflector 103, the etching bottom surface can be controlled relatively roughly. The depth of the hole H is not particularly limited, but the hole preferably has such a depth that a side surface of at least one of InP layers of the semiconductor multilayer film reflector 103 is in contact with the second part 102b of the metal film 102. This is for the purpose of taking advantage of the function of the InP layers to discharge heat in the lateral direction.

### <8. Surface Emitting Laser According to Example 8 of the Embodiment of Present Technology>

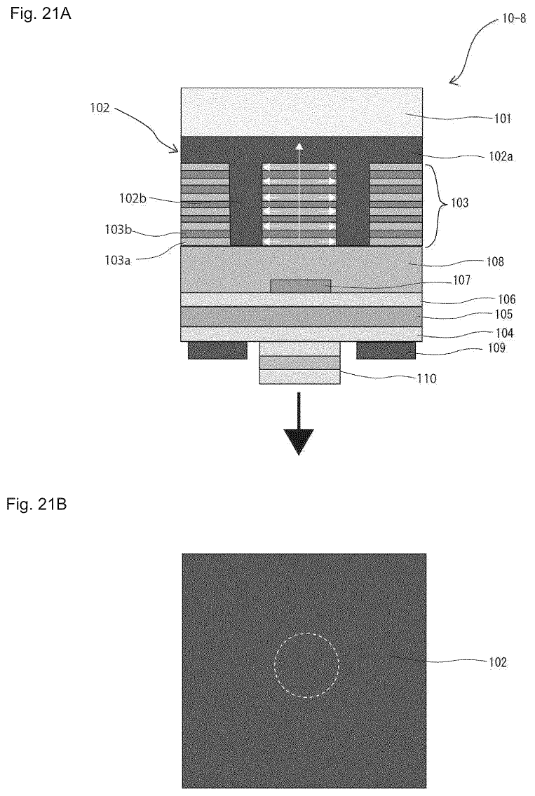

Hereinafter, a surface emitting laser according to Example 8 of the embodiment of the present technology will be described. FIG. 21A is a cross-sectional view of the surface emitting laser 10-8 according to Example 8 of the embodiment of the present technology. FIG. 21B is a plan view of a semiconductor multilayer film reflector in which a part of the metal film 102 of the surface emitting laser 10-8 according to Example 8 of the embodiment of the present technology is provided.

The surface emitting laser 10-8 according to Example 8 is substantially the same as the surface emitting laser 10-2 according to Example 2 except that the first and second reflectors are exchanged as shown in FIGS. 21A and 21B.

In the surface emitting laser 10-8, the first reflector includes a reflector 110, and the second reflector includes a semiconductor multilayer film reflector 103 and a metal film 102.

In the surface emitting laser 10-8, the semiconductor multilayer film reflector 103, the metal film 102, and the substrate 101 are arranged on the side (upper side) of the embedding layer 108 opposite to the active layer 105, and the reflector 110 and the anode electrode 109 are arranged on the side (lower side) of the first cladding layer 104 opposite to the side of the active layer 105.

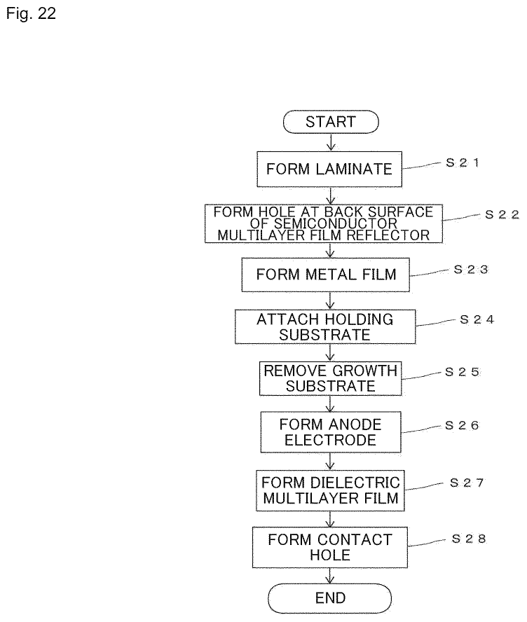

Hereinafter, a method for manufacturing the surface emitting laser 10-8 will be described with reference to the flowchart (steps S21 to S28) in FIG. 22 and FIGS. 23A to 26B. Here, a plurality of surface emitting lasers 10-8 are simultaneously produced on a single wafer that serves as a base material for the substrate 101 by a semiconductor manufacturing method using a semiconductor manufacturing device by way of illustration. Then, the plurality of integrally formed surface emitting lasers 10-8 are separated into the plurality of surface emitting lasers 10-8 in a chip form (surface emitting laser chips). For example, the surface emitting lasers 10-8 are produced by a semiconductor manufacturing device according to the procedure in the flowchart in FIG. 22.

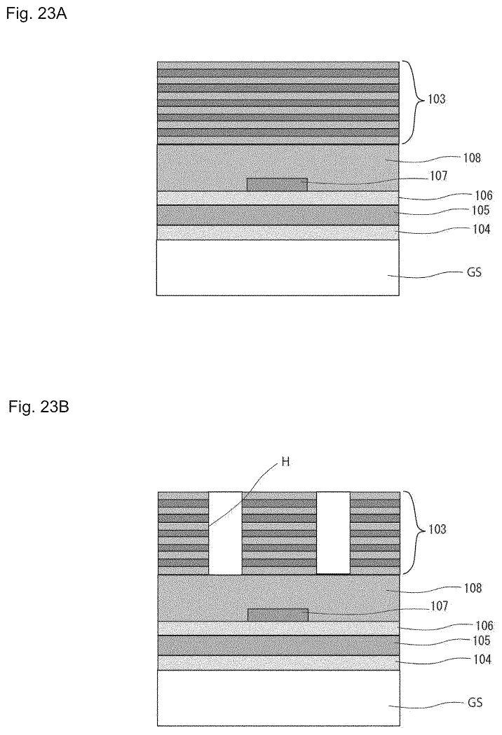

In the first step S21, a laminate is produced (see FIG. 23A). Specifically, as an example, an etch-stop layer (e.g., an InGaAsP layer and an AlGaInAs layer), a first cladding layer 104, an active layer 105, a second cladding layer 106, a tunnel junction layer 107, an embedding layer 108, and a semiconductor multilayer film reflector 103 are formed in this order on a growth substrate GS (e.g., InP substrate) in a growth chamber by metal organic vapor deposition (MOCVD) or molecular beam epitaxy (MBE).

In the following step S22, a hole H is formed on the back surface of the semiconductor multilayer film reflector 103 (see FIG. 23B). More specifically, a resist pattern to cover the part of the semiconductor multilayer film reflector 103 other than the part for forming the back surface hole H is formed, and the hole H is formed by etching the semiconductor multilayer film reflector 103 for example by dry etching using the resist pattern as a mask. The etching is performed to such a depth that the embedding layer 108 is exposed. As a result, the hole H is formed to penetrate the semiconductor multilayer film reflector 103.

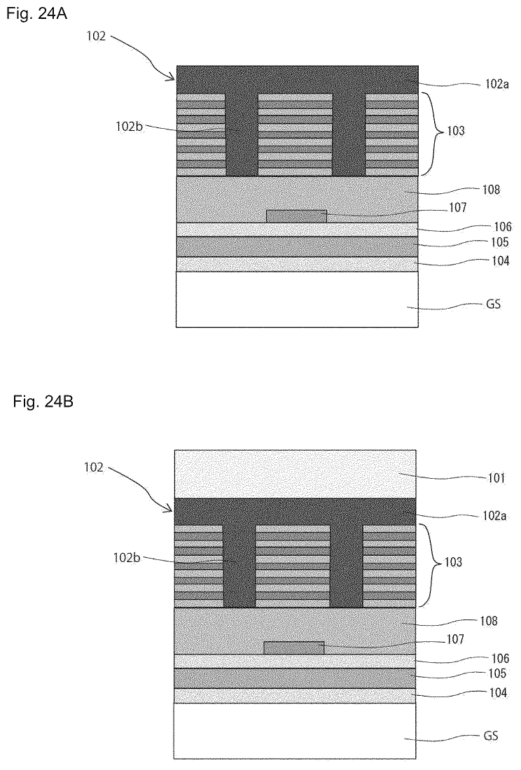

In the following step S23, the metal film 102 is formed (see FIG. 24A).

Specifically, to start with, a thin Au film for example is formed on the back surface of the semiconductor multilayer film reflector 103 and in the hole H by vapor deposition, and the thin Au film as a seed is further plated with Au and formed into a thick film, the hole H is filled with a part of the thick Au film, and a further part of the Au thick film is formed flat on the back surface of the semiconductor multilayer film reflector 103. The further part of the thick Au film is polished and planarized by a CMP device.

In the following step S24, a substrate 101 as a holding substrate is attached (see FIG. 24B). Specifically the substrate 101 is attached to the metal film 102 for example through Ag paste (conductive adhesive).

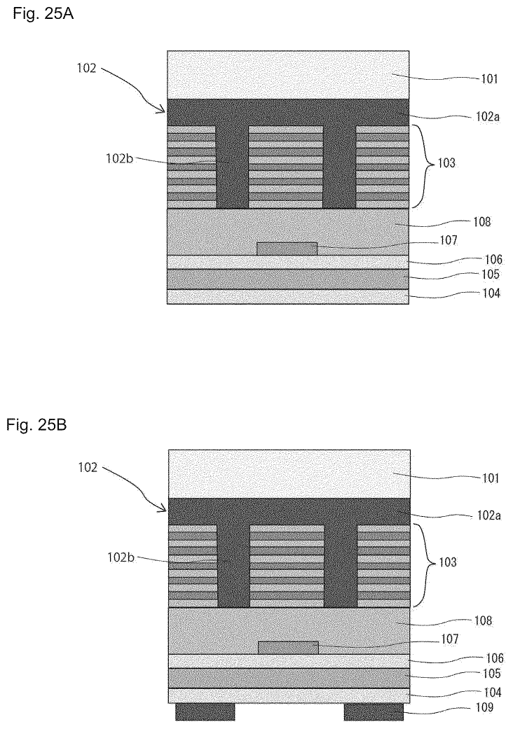

In the following step S25, the growth substrate GS is removed (see FIG. 25A). Specifically to start with, the back surface of the growth substrate GS (see FIG. 24B) is ground roughly with a back grinder, and the remaining part is removed by wet etching. During the process, the etching can be stopped at the etch stop layer, and only the growth substrate GS can be removed. Then, the etch stop layer is removed by another kind of etchant to expose the first cladding layer 104.

In the following step S26, an anode electrode 109 is formed (see FIG. 25B). Specifically the frame-shaped (e.g., such as an annular shape) anode electrode 109 is formed on the first cladding layer 104 to surround the region corresponding to the tunnel junction layer 107 for example by lifting off.

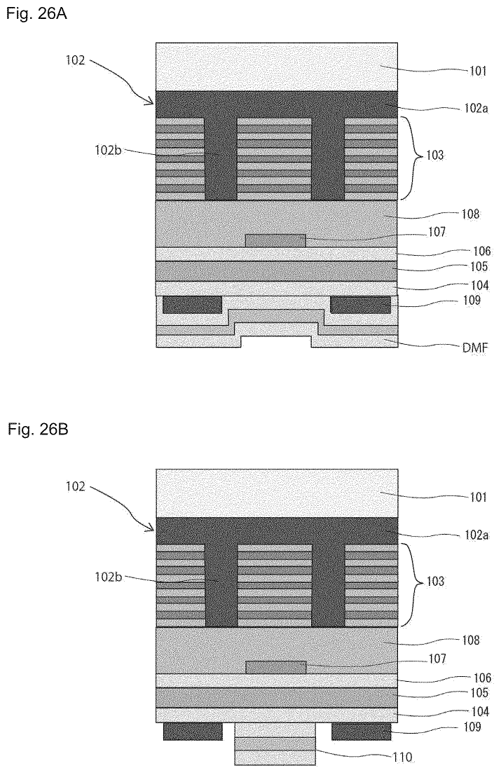

In the following step S27, a dielectric multilayer film DMF is deposited (see FIG. 26A). Specifically, dielectric multilayer film DMF which is a material for the reflector 110 is deposited on the entire surface of the laminate in which the anode electrode 109 is formed.

In the following step S28, a contact hole is formed (see FIG. 26B). Specifically the part of the dielectric multilayer film DMF that covers the anode electrode 109 is removed for example by dry etching, so that a contact hole is formed to expose the anode electrode 109. As a result, the reflector 110 is formed.

In the above-described method for manufacturing the surface emitting laser 10-8, the step of attaching the support substrate SB (temporary attaching step) and the step of removing the support substrate SB can be eliminated, and thus the manufacturing man-hours can be reduced.

### <9. Surface Emitting Laser According to Example 9 of the Embodiment of Present Technology>

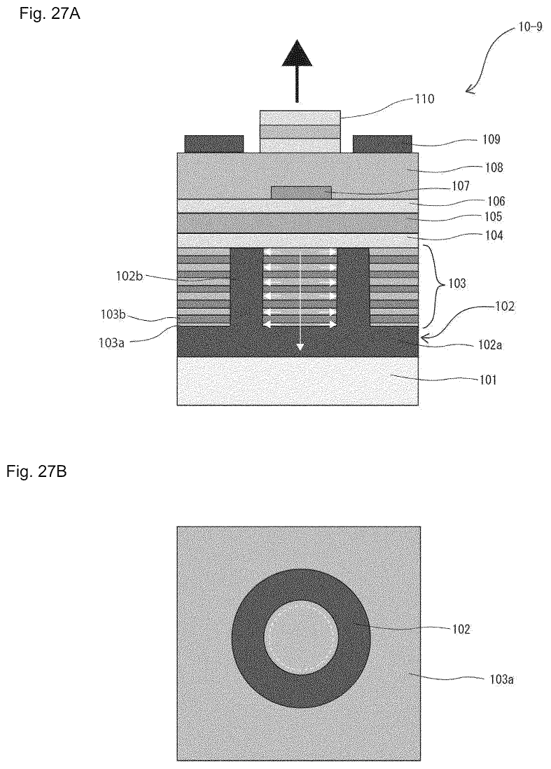

Hereinafter, a surface emitting laser 10-9 according to Example 9 of the embodiment of the present technology will be described. FIG. 27A is a cross-sectional view of the surface emitting laser 10-9 according to Example 9 of the embodiment of the present technology. FIG. 27B is a plan view of a semiconductor multilayer film reflector in which a part of the metal film 102 of the surface emitting laser 10-9 according to Example 9 of the embodiment of the present technology is provided.

As shown in FIGS. 27A and 27B, the surface emitting laser 10-9 has substantially the same configuration as that of the surface emitting laser 10-2 according to Example 2 except that one amorphous layer 103a (the furthermost amorphous layer 103a from the active layer 105), one surface of which is the back surface of the semiconductor multilayer film reflector 103, has a thickness different from the thickness of the other amorphous layers 103a in the semiconductor multilayer film reflector 103.

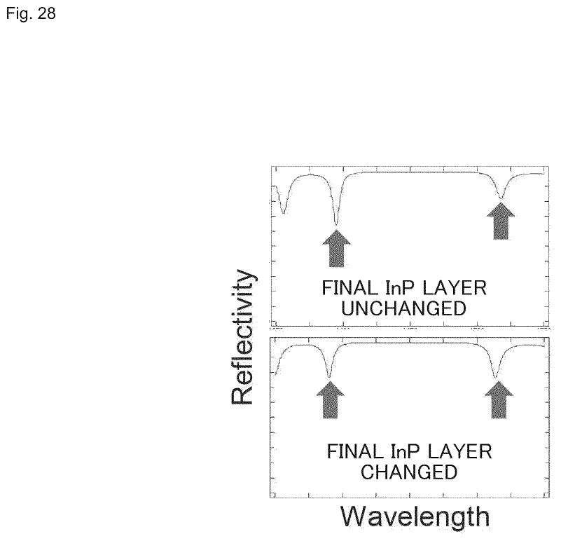

Meanwhile, since the reflective properties of the epi-DBR and the metal film are significantly different, a phase shift occurs at the interface between the epi-DBR and the metal film. This may cause a deviation in the reflectance characteristic of the epi-DBR, and the symmetry may be disrupted (see the upper part in FIG. 28). It is important to improve the asymmetry and obtain good reflectance characteristic in the epi-DBR with a narrow stopband width. The phase shift can be improved by adjusting the thickness of the bottommost layer (final InP layer) of the epi-DBR (see the lower part in FIG. 28).

For example, in the surface emitting laser 10-9, the thickness of the amorphous layer 103a, one surface of which is the back surface of the semiconductor multilayer film reflector 103, is smaller than the thickness of the other amorphous layers 103a.

The surface emitting laser 10-9 can be manufactured by substantially the same method as the method for manufacturing the surface emitting laser 10-2 according to Example 2.

The surface emitting laser 10-9 can exhibit the same advantageous effect as that of the surface emitting laser 10-2 according to Example 2, and the semiconductor multilayer film reflector 103 which is the epi-DBR having a reflection characteristic with high symmetry can be provided.

### <10. Surface Emitting Laser According to Example 10 of the Embodiment of Present Technology>

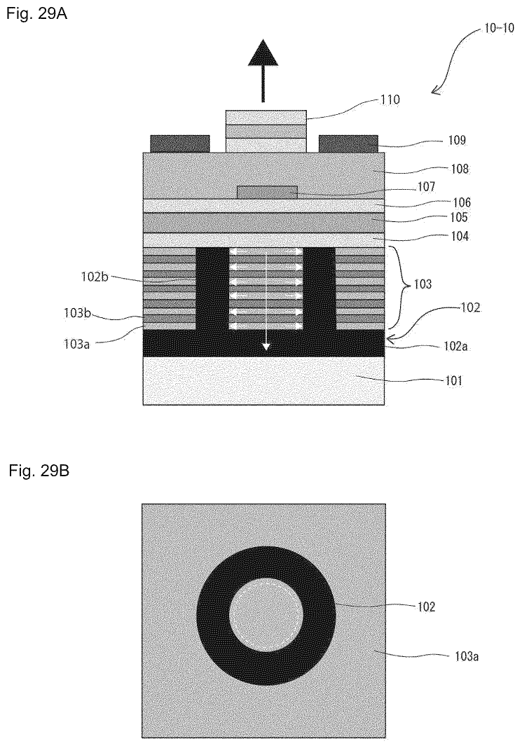

Hereinafter, a surface emitting laser 10-10 according to Example 10 of the embodiment of the present technology will be described. FIG. 29A is a cross-sectional view of the surface emitting laser 10-10 according to Example 10 of the embodiment of the present technology. FIG. 29B is a plan view of a semiconductor multilayer film reflector in which a part of the metal film 102 of the surface emitting laser 10-10 according to Example 10 of the embodiment of the present technology is provided.

The surface emitting laser 10-10 has the same configuration as that of the surface emitting laser 10-2 according to Example 2 except that the material of the metal film 102 has high reflectance with respect to a desired wavelength and high thermal conductivity.

Examples of the material of the metal film 102 include Au, Ag, Al, and Cu. These materials have a reflectance characteristic as high as 90% or more with respect to light having a wavelength longer than the 1300 nm band, which is the target of the InP-based VCSEL, and a thermal conductivity as high as 200 W/m-k or more. These materials are also highly useful as the materials may be used in semiconductor processes.

The surface emitting laser 10-10 can be manufactured by the same manufacturing method as the method for manufacturing the surface emitting laser 10-2 according to Example 2.

### <11. Surface Emitting Laser According to Example 11 of the Embodiment of Present Technology>

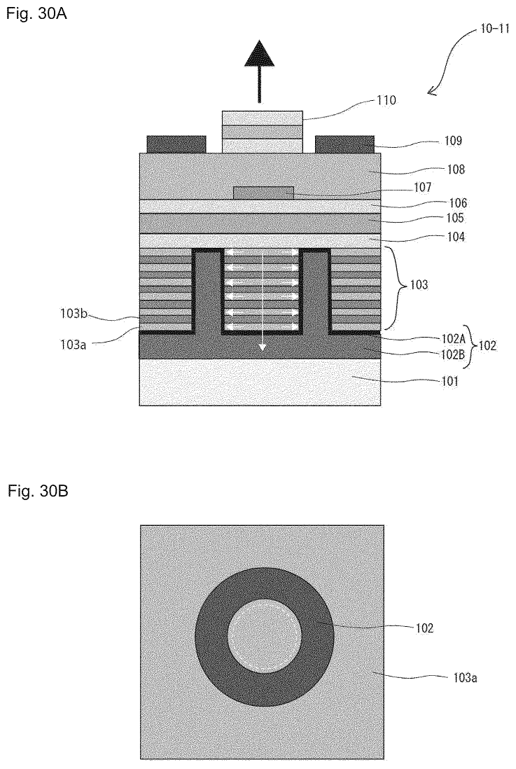

Hereinafter, a surface emitting laser 10-11 according to Example 11 of the embodiment of the present technology will be described. FIG. 30A is a cross-sectional view of the surface emitting laser 10-11 according to Example 11 of the embodiment of the present technology. FIG. 30B is a plan view of a semiconductor multilayer film reflector in which a part of the metal film 102 of the surface emitting laser 10-11 according to Example 11 of the embodiment of the present technology is provided.

As shown in FIGS. 30A and 30B, the surface emitting laser 10-11 has the same configuration as that of the surface emitting laser 10-2 according to Example 2 except that the metal film 102 has a stacked structure including a plurality of (for example two) metal layers 102A and 102B made of different kinds of metal stacked on each other.

Meanwhile, reflectance and thermal conductivity are different among different kinds of metal. In addition, Ag, for example, is easily oxidized and difficult to handle. Therefore, in the surface emitting laser 10-11, for example Ag with high reflectance and Au with relatively high reflectance and high stability are used for the first metal layer 102A in contact with the semiconductor multilayer film reflector 103, and Cu, which has high thermal conductivity and is easily thickened by plating, is used for the second metal layer 102B provided on the first metal layer 102A.

In this way, since the metal film 102 has a stacked structure including a plurality of metal layers made of different types of metal, the metal layers can be used in a suitable arrangement, and both high reflectance and high heat dissipation can be achieved. In particular, it is effective to use Ag in the layer positioned closer to the semiconductor multilayer film reflector 103 in the stacked structure, because Ag has good reflectance and thermal conductivity but is prone to degradation due to oxidation.

The surface emitting laser 10-11 can be manufactured by substantially the same method as the method for manufacturing the surface emitting laser 10-2 according to Example 2.

### <12. Surface Emitting Laser According to Example 12 of the Embodiment of Present Technology>

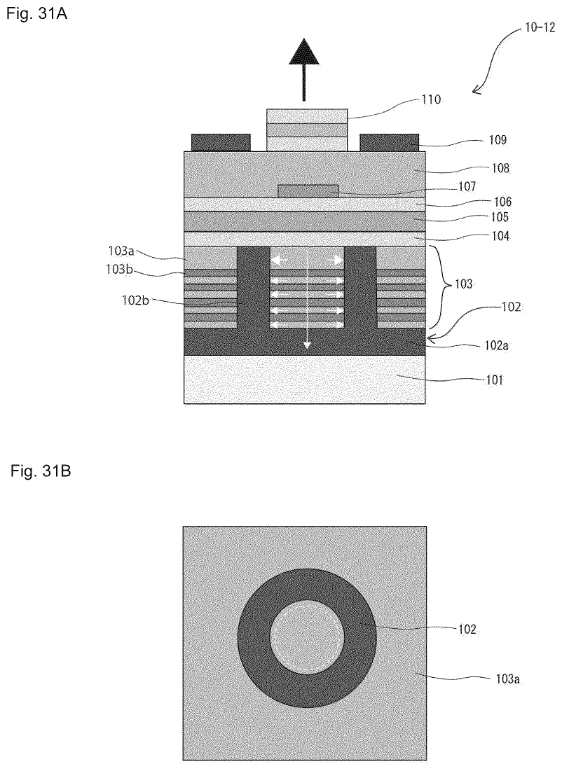

Hereinafter, a surface emitting laser 10-12 according to Example 12 of the embodiment of the present technology will be described. FIG. 31A is a cross-sectional view of the surface emitting laser 10-12 according to Example 12 of the embodiment of the present technology. FIG. 31B is a plan view of a semiconductor multilayer film reflector in which a part of the metal film 102 of the surface emitting laser 10-12 according to Example 12 of the embodiment of the present technology is provided.

As shown in FIGS. 31A and 31B, the surface emitting laser 10-12 has the same configuration as that of the surface that of the surface emitting laser 10-2 according to Example 2 except that the optical thickness of the amorphous layer 103a of a part of the semiconductor multilayer film reflector 103 is expressed by (m+2)λ/4 (m>1). In the expression, λ indicates the oscillation wavelength of the surface emitting laser 10-12.

Meanwhile, the surface emitting laser 10-2 according to Example 2 has a structure that efficiently dissipates heat to the metal film 102 through the InP layer, which is an amorphous layer of the semiconductor multilayer film reflector 103. In order to make most of the structure, it is effective to increase the thickness of some (at least one) of the InP layers of the semiconductor multilayer film reflector 103. However, the optical thickness of the InP layer should be (m+2)/4λ (m>1) in order to prevent deterioration of the reflection characteristic. The optical thickness of the InP and AlGaInAs layers in the further part of the semiconductor multilayer film reflector 103 is for example set to λ/4.

For example, in the surface emitting laser 10-12, the optical thickness of the InP layer, which is the amorphous layer 103a of the semiconductor multilayer film reflector 103 that is the closest to the active layer 105 is set to ¾λ. This allows for improved heat dissipation without deteriorating the reflective characteristics.

Which InP layer to be thickened and the number of the InP layers to be thickened can be changed as required. The InP layers closer to the heat-generating area have a greater heat-dissipation effect when thickened. Also, as the number of the InP layers that are made thicker increases, the heat dissipation effect increases.

Meanwhile, since thicker InP layers tend to deteriorate the reflectance characteristic, to strike a balance between heat dissipation and reflectance characteristic is necessary. Specifically, the semiconductor multilayer film reflector 103 desirably has at most three InP layers with an optical thickness of ¾λ.

The surface emitting laser 10-12 can be manufactured by substantially the same method as the method for manufacturing the surface emitting laser 10-2 according to Example 2.

### <13. Surface Emitting Laser According to Example 13 of the Embodiment of Present Technology>

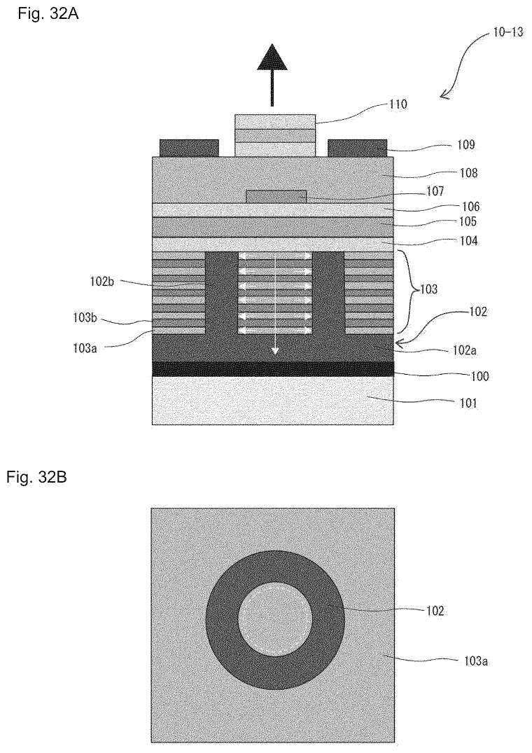

Hereinafter, a surface emitting laser 10-13 according to Example 13 of the embodiment of the present technology will be described. FIG. 32A is a cross-sectional view of the surface emitting laser 10-13 according to Example 13 of the embodiment of the present technology FIG. 32B is a plan view of a semiconductor multilayer film reflector in which a part of the metal film 102 of the surface emitting laser 10-13 according to Example 13 of the embodiment of the present technology is provided.

As shown in FIG. 32A and FIG. 32B, the surface emitting laser 10-13 has the same configuration as that of the surface emitting laser 10-2 according to Example 2 except that the metal film 102 and the substrate 101 are bonded through another metal film 100.

The metal film 100 is made of the same type of metal as the metal film 102 (for example Au, Ag, Al, or Cu). The metal film 102 and the metal film 100 are directly bonded by metal bonding. The metal film 102 and the metal film 100 may be made of different kinds of metal.

The substrate 101 is, though not particularly limited, preferably a substrate (e.g., silicon substrate) that has high thermal conductivity and is inexpensive.

### <14. Surface Emitting Laser According to Example 14 of the Embodiment of Present Technology>

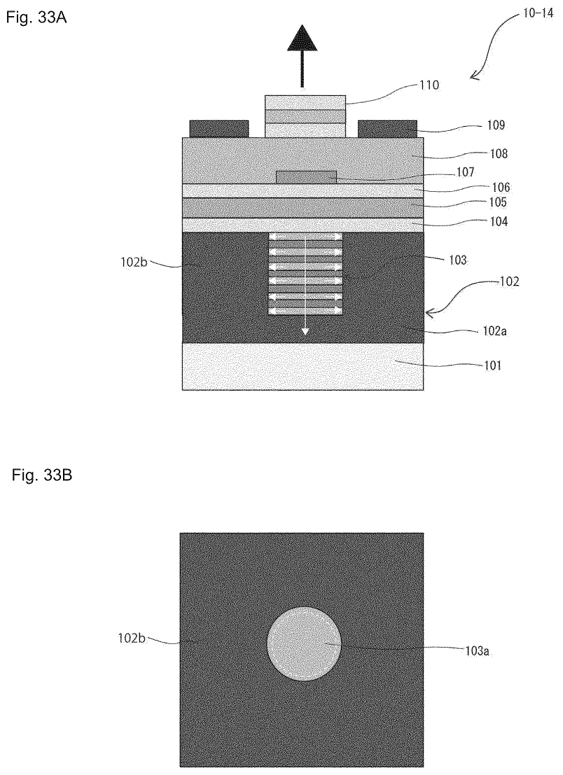

Hereinafter, a surface emitting laser 10-14 according to Example 14 of the embodiment of the present technology will be described. FIG. 33A is a cross-sectional view of the surface emitting laser 10-14 according to Example 14 of the embodiment of the present technology. FIG. 33B is a plan view of a semiconductor multilayer film reflector around which a part of the metal film 102 of the surface emitting laser 10-14 according to Example 14 of the embodiment of the present technology is provided.

As shown in FIGS. 33A and 33B, the surface emitting laser 10-14 has the same configuration as that of the surface emitting laser 10-2 according to Example 2 except that the semiconductor multilayer film reflector 103 has only a region corresponding to the light emission region of the active layer 105, and the metal film 102 is provided on the side surface and back surface sides of the semiconductor multilayer film reflector 103.

The surface emitting laser 10-14 can be manufactured by substantially the same method as the method for manufacturing the surface emitting laser 10-2 according to Example 2.

In the surface emitting laser 10-14, the rigidity of the semiconductor multilayer film reflector 103 is somewhat sacrificed, but since the semiconductor multilayer film reflector 103 has a structure in which the entire region except for the region corresponding to the light emission region is replaced with the metal film (as the volume of the metal film 102 is very large), the heat dissipation is greatly improved.

### <15. Surface Emitting Laser According to Example 15 of the Embodiment of Present Technology>

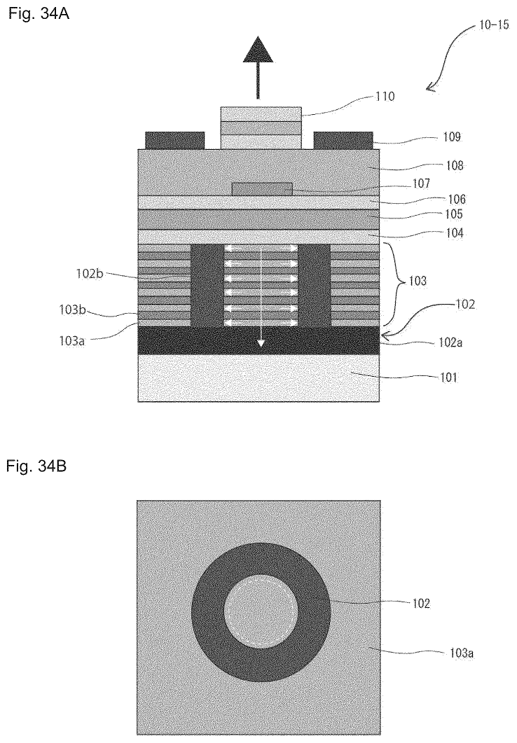

Hereinafter, a surface emitting laser 10-15 according to Example 15 of the embodiment of the present technology will be described. FIG. 34A is a cross-sectional view of the surface emitting laser 10-15 according to Example 15 of the embodiment of the present technology. FIG. 34B is a plan view of the semiconductor multilayer film reflector in which a part of the metal film 102 of the surface emitting laser 10-15 according to Example 15 of the embodiment of the present technology is provided.

As shown in FIGS. 34A and 34B, the surface emitting laser 10-15 has the same configuration as that of the surface emitting laser 10-2 according to Example 2 except that the first and second parts 102a and 102b of the metal film 102 are made of different kinds of metal.

In the surface emitting laser 10-15, for example Cu or Al may be used for the first part 102a, and for example Au or Ag may be used for the second part 102a.

The surface emitting laser 10-15 can be manufactured by substantially the same method as the method for manufacturing the surface emitting laser 10-2 according to Example 2.

The surface emitting laser 10-15 has the same advantageous effect as the surface emitting laser 10-11 according to Example 11.

### <16. Surface Emitting Laser According to Example 16 of the Embodiment of Present Technology>

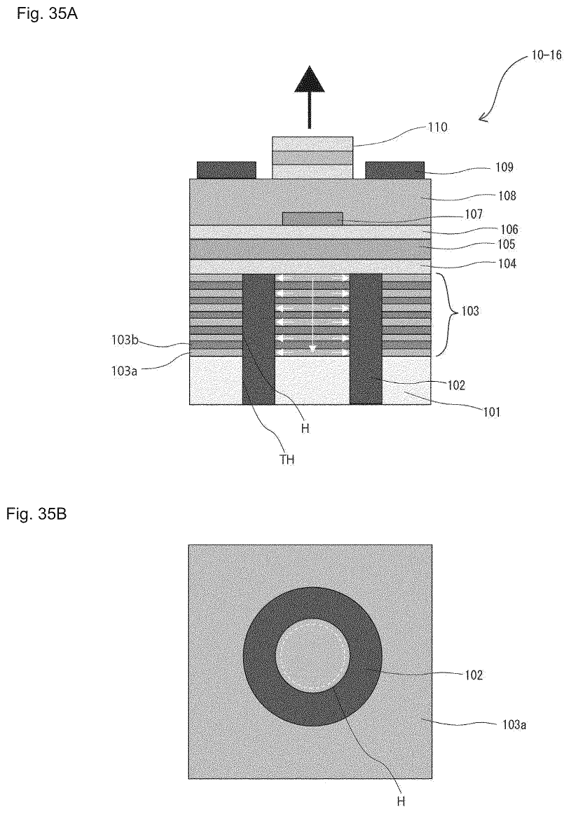

Hereinafter, a surface emitting laser 10-16 according to Example 16 of the embodiment of the present technology will be described. FIG. 35A is a cross-sectional view of the surface emitting laser 10-16 according to Example 16 of the embodiment of the present technology. FIG. 35B is a plan view of a semiconductor multilayer film reflector in which a part of the metal film 102 of the surface emitting laser 10-16 according to Example 16 of the embodiment of the present technology is provided.

As shown in FIGS. 35A and 35B, the surface emitting laser 10-16 has the same configuration as that of the surface emitting laser 10-12 according to Example 2 except that the metal film 102 is tubular as a whole and is provided to penetrate the semiconductor multilayer film reflector 103 and the substrate 101.

In the surface emitting laser 10-16, since the first reflector includes only the semiconductor multilayer film reflector 103, the number of pairs must necessarily be increased, and a wider stop bandwidth cannot be expected, but since the metal film 102 penetrates the semiconductor multilayer film reflector 103 and the substrate 101, heat from the active layer 105 and the tunnel junction layer 107 as the heat-generating part can be directly discharged externally (to the outside) from the substrate 101 through the metal film 102, which is effective for excellent heat dissipation. In the surface emitting laser 10-16, since no metal film is provided on the back surface of the semiconductor multilayer film reflector 103, for example, the back surface (lower surface) of the substrate 101 can be used as the emission surface. In this case, however, a transparent substrate must be used for the substrate 101 for an oscillation wavelength λ.

The surface emitting laser 10-16 can be manufactured by performing steps S11 to S17 in the flowchart in FIG. 11, then attaching the substrate 101 to the back surface of the semiconductor multilayer film reflector 103, forming a through hole TH at a position corresponding to the hole H in the substrate 101 by photolithography, and filling the hole H and the through hole TH with the metal film 102.

### <17. Surface Emitting Laser According to Example 17 of the Embodiment of Present Technology>

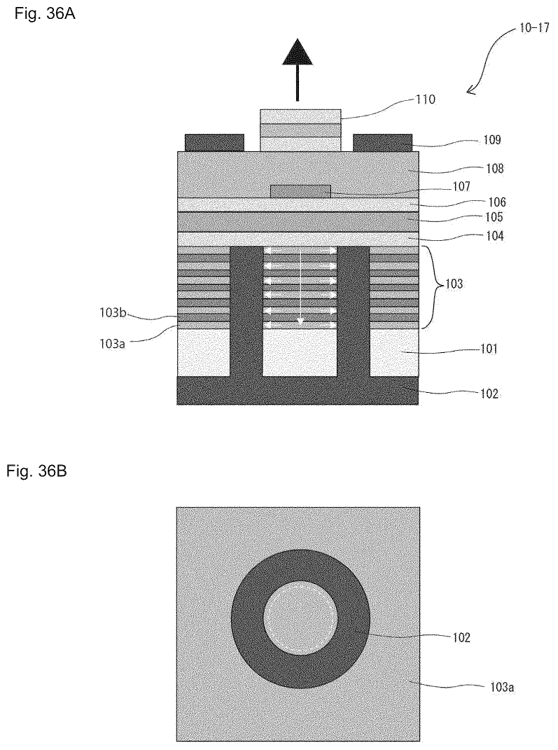

Hereinafter, a surface emitting laser 10-17 according to Example 17 of the embodiment of the present technology will be described. FIG. 36A is a cross-sectional view of the surface emitting laser 10-17 according to Example 17 of the embodiment of the present technology FIG. 36B is a plan view of a semiconductor multilayer film reflector in which a part of the metal film 102 of the surface emitting laser 10-17 according to Example 17 of the embodiment of the present technology is provided.

As shown in FIGS. 36A and 36B, the surface emitting laser 10-17 has the same configuration as that of the surface emitting laser 10-16 according to Example 16 except that the metal film 102 is also provided on the back (lower) surface of the substrate 101.

The surface emitting laser 10-17 can be manufactured by the same manufacturing method as the method for the surface emitting laser 10-16 according to Example 16 except that the metal film 102 is also deposited on the back surface of the substrate 101.

The surface emitting laser 10-17 may have improved heat dissipation since the area of the metal film 102 exposed to the outside is larger than that of the surface emitting laser 10-16 according to Example 16.

### <18. Surface Emitting Laser According to Example 18 of the Embodiment of the Present Technology>

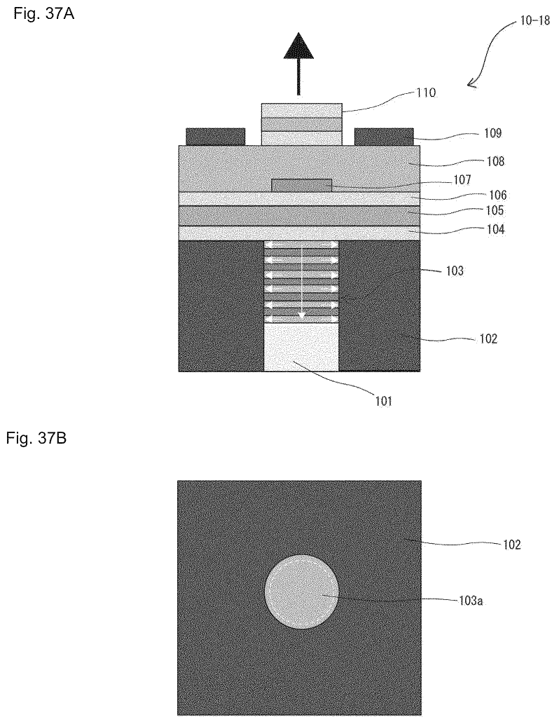

Hereinafter, a surface emitting laser 10-18 according to Example 18 of the embodiment of the present technology will be described. FIG. 37A is a cross-sectional view of the surface emitting laser 10-18 according to Example 18 of the embodiment of the present technology. FIG. 37B is a plan view of a semiconductor multilayer film reflector around which a part of the metal film 102 of the surface emitting laser 10-18 according to Example 18 of the embodiment of the present technology is provided.

As shown in FIGS. 37A and 37B, the surface emitting laser 10-18 has the same configuration as that of the surface emitting laser 10-16 according to Example 16 except that the region around the region of the semiconductor multilayer film reflector 103 and the substrate 101 corresponding to the light emission region of the active layer 105 is replaced by the metal film 102.

The surface emitting laser 10-18 can be manufactured by substantially the same method as the method for manufacturing the surface emitting laser 10-16.

When compared to the surface emitting laser 10-16 according to Example 16, in the surface emitting laser 10-18, the part of the metal film 102 exposed to the outside on the side surface side of the semiconductor multilayer film reflector 103 and the side surface side of the substrate 101 has a greater volume, the heat dissipation can be further improved. In the surface emitting laser 10-18, since no metal film is provided on the back surface of the semiconductor multilayer film reflector 103, for example, the back surface (lower surface) of the substrate 101 can be used as the emission surface. In this case, however, a transparent substrate must be used for the substrate 101 for an oscillation wavelength λ.

### <19. Surface Emitting Laser According to Example 19 of the Embodiment of Present Technology>

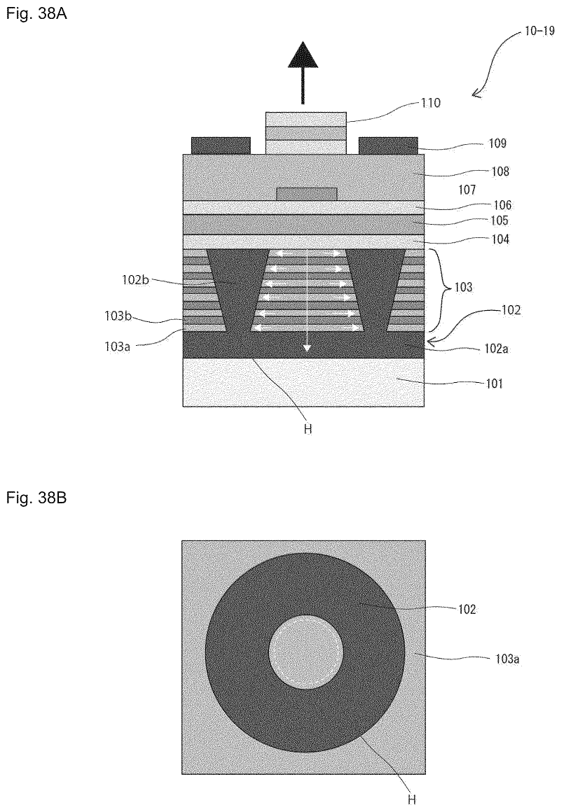

Hereinafter, a surface emitting laser 10-19 according to Example 19 of the embodiment of the present technology will be described. FIG. 38A is a cross-sectional view of the surface emitting laser 10-19 according to Example 19 of the embodiment of the present technology. FIG. 38B is a plan view of a semiconductor multilayer film reflector in which a part of the metal film 102 of the surface emitting laser 10-19 according to Example 19 of the embodiment of the present technology is provided.

As shown in FIGS. 38A and 38B, the surface emitting laser 10-19 has the same configuration as that of the surface emitting laser 10-2 according to Example 2 except that the second part 102b of the metal film 102 is reversely tapered in side view (the width of the part is reduced as the distance from the active layer 105 increases).

The surface emitting laser 10-19 can be manufactured by the same method as the method for manufacturing the surface emitting laser 10-2 according to Example 2.

In the surface emitting laser 10-19, the contact area between the side surface of the semiconductor multilayer film reflector 103 (inner surface of the hole H) and the second part 102b of the metal film 102 can be increased, and since the metal film 102 has a shape in which a part closer to the heat generating part is closer to the center (a reversely tapered shape), heat dissipation can be further improved.

### <20. Surface Emitting Laser According to Example 20 of the Embodiment of Present Technology>

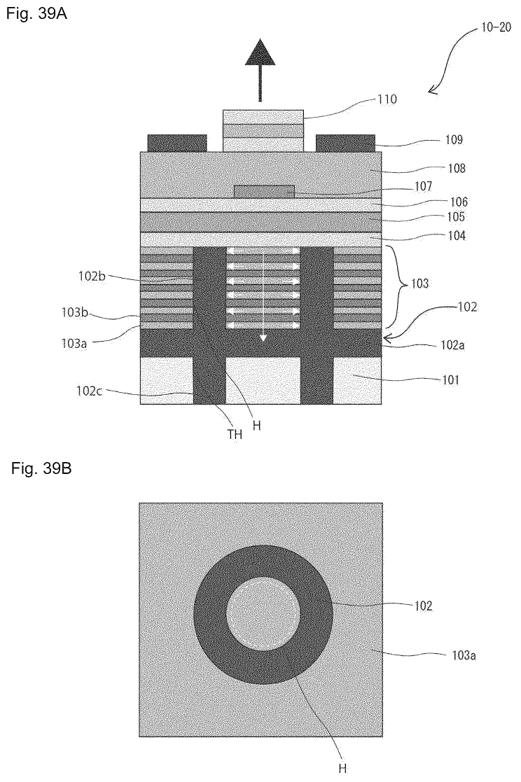

Hereinafter, a surface emitting laser 10-20 according to Example 20 of the embodiment of the present technology will be described. FIG. 39A is a cross-sectional view of the surface emitting laser 10-20 according to Example 20 of the embodiment of the present technology. FIG. 39B is a plan view of a semiconductor multilayer film reflector in which a part of the metal film 102 of the surface emitting laser 10-20 according to Example 20 of the embodiment of the present technology is provided.

As shown in FIGS. 39A and 39, the surface emitting laser 10-20 has the same configuration as that of the surface emitting laser 10-2 according to Example 2 except that the metal film 102 has a third part 102c that penetrates a position corresponding to the second part 102b of the substrate 101.

The surface emitting laser 10-20 can be manufactured by executing steps S1 to S19 in the flowchart in FIG. 11, forming a through hole TH at a position corresponding to the second part 102b of the substrate 101, filling the through hole TH with a metal material (a metal material which is the same as or different from the metal material of the first and second parts 102a and 102c) to be the third part 102c, and executing step S20 in FIG. 11.

In the surface emitting laser 10-20, since the area of the part of the metal film 102 exposed to the outside is large, the heat dissipation can be further improved.

### <21. Modifications of Present Technology>

The present technology is not limited to the above examples and can be modified in various manners.

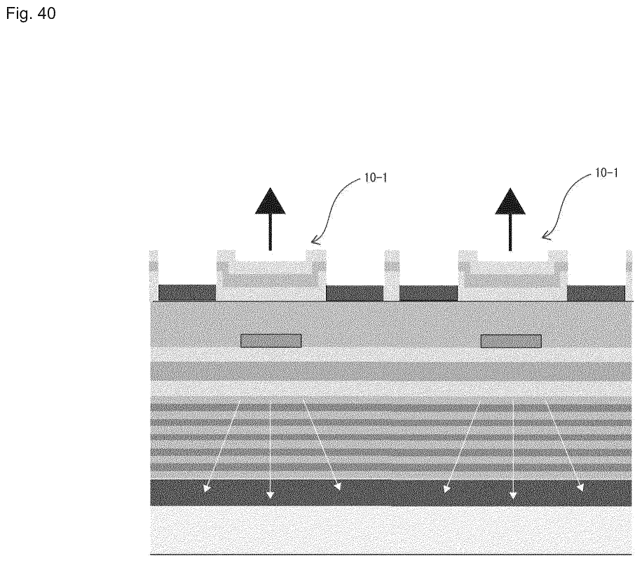

For example, as shown in FIG. 40, a surface emitting laser array can be provided by arranging a plurality of the surface emitting lasers 10-1 according to Example 1 in an array form. As an example, the surface emitting laser array can be formed by simultaneously producing a plurality of surface emitting laser arrays including a plurality of surface emitting lasers 10-1 on a single wafer that serves as a base material for a substrate 101 by a semiconductor manufacturing method using a semiconductor manufacturing device, and separating the plurality of integrally formed surface emitting laser arrays into a plurality of surface emitting laser arrays in a chip form (surface emitting laser array chips) by dicing.

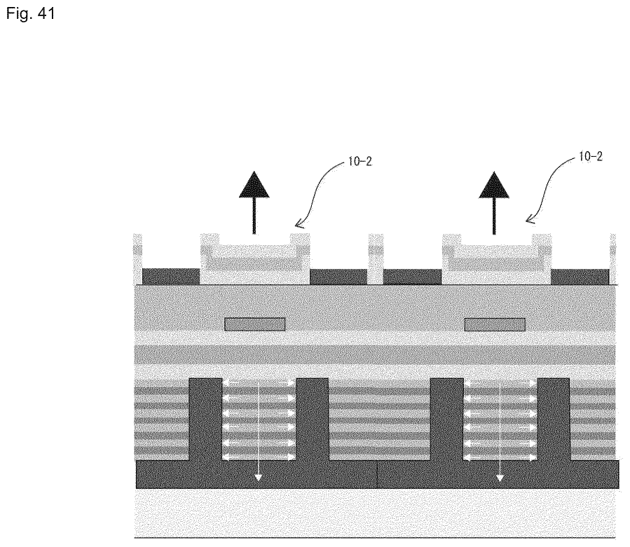

For example, as shown in FIG. 41, a surface emitting laser array having a plurality of the surface emitting lasers 10-2 according to Example 2 arranged in an array form can also be manufactured. The surface emitting laser array can also be manufactured using the same manufacturing method as the method for manufacturing the surface emitting laser array shown in FIG. 35.

Similarly a surface emitting laser array having a plurality of surface emitting lasers according to any of Examples 3 to 20 arranged in an array form can be provided.

In the surface emitting lasers according to the above-described examples, the semiconductor multilayer film reflector 103 has pairs of amorphous and mixed crystal layers but may also have pairs of mixed crystal layers (e.g., AlGaInAs/AlGaInAs). In other words, the surface emitting laser according to the present technology can be used for InP-based VCSELs with semiconductor multilayer film reflectors made of InP-based compound semiconductors in general and exhibit highly advantageous effects (high reflectance and high heat dissipation).

For example, a QD active layer (quantum dot active layer) may be used for the active layer 105.

The surface emitting lasers according to the above examples do not have to include a substrate 101.

Some of the configurations of the surface emitting lasers according to the described examples may be combined to the extent that there is no contradiction between each other.

The material, conductivity thickness, width, length, shape, size, arrangement, or other elements of the components of the surface emitting lasers according to the above examples may be changed as appropriate within the range in which the laser functions as a surface emitting laser.

### <22. Example of Application to Electronic Device>

The technology according to the present disclosure (the present technology) can be applied to various products (electronic devices). For example, the technology according to the present disclosure may be realized as a device equipped in any type of moving body such as an automobile, an electric vehicle, a hybrid electric vehicle, a motorcycle, a bicycle, a personal mobility device, an airplane, a drone, a ship, and a robot.

The surface emitting laser according to the present technology may be used for example as a light source for a device that forms or displays images by a laser beam (such as a laser printer, a laser copier, a projector, a head mounted display and a head-up display).

### <23. Example of Application of Surface Emitting Laser to Distance Measurement Device>

Hereinafter, examples of application of the surface emitting lasers according to the above examples will be described.

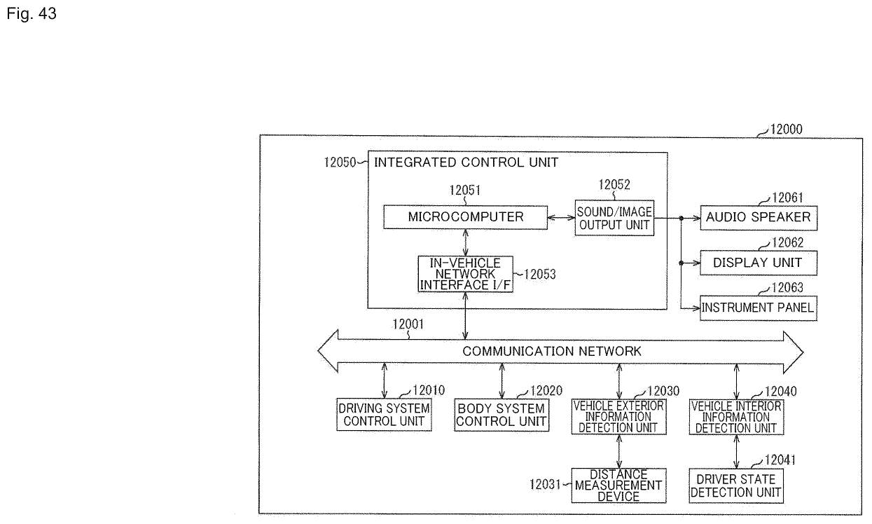

FIG. 43 shows an exemplary overall configuration of a distance measurement device 1000 including a surface emitting laser 10-1 as an example of an electronic device. The distance measurement device 1000 measures the distance to a test object S using the TOF (Time Of Flight) method. The distance measurement device 1000 includes a surface emitting laser 10-1 as a light source. The distance measurement device 1000 may include a surface emitting laser 10-1, a light receiving device 125, lenses 115 and 135, a signal processing unit 140, a control unit 150, a display unit 160, and a storage unit 170.

The light receiving device 125 detects light reflected by the test object S. The lens 115 is a collimating lens to collimate light emitted from the surface emitting laser 10-1. The lens 135 is a condenser lens to collect the light reflected by the test object S and guide the collected light to the light receiving device 125.

The signal processing unit 140 is a circuit for generating a signal corresponding to the difference between a signal input from the light receiving device 125 and a reference signal input from the control unit 150. The control unit 150 may include a Time to Digital Converter (TDC). The reference signal may be a signal input from the control unit 150 or an output signal from a detection unit that directly detects an output from the surface emitting laser 10-1. The control unit 150 may be a processor that controls the surface emitting laser 10-1, the light receiving device 125, the signal processing unit 140, the display unit 160, and the storage unit 170. The control unit 150 is a circuit that measures the distance to the test object S on the basis of a signal generated by the signal processing unit 140. The control unit 150 generates a video signal for displaying information about the distance to the test object S and outputs the signal to the display unit 160. The display unit 160 displays information about the distance to the test object S on the basis of the video signal input from the control unit 150. The control unit 150 stores the information about the distance to the test object S in the storage unit 170.

In this exemplary application, any of the above surface emitting lasers 10-1 to 10-20 can be used for the distance measurement device 1000 instead of the surface emitting laser 10-1.

### <24. Example of Providing Distance Measurement Device to Moving Body>

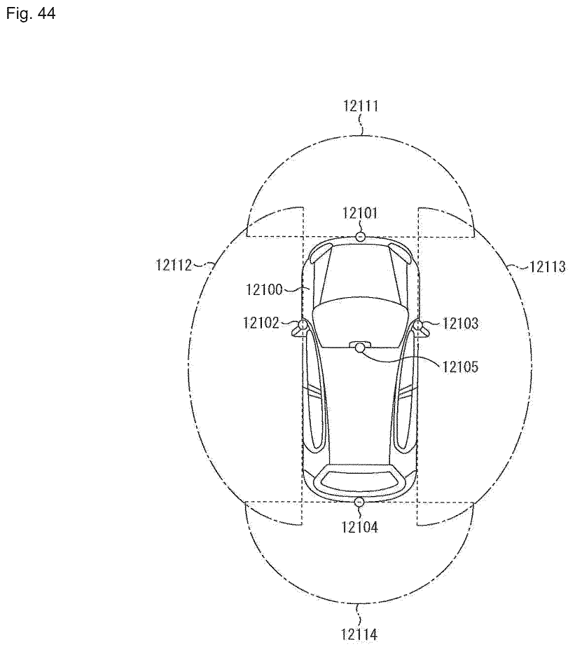

FIG. 44 is a block diagram illustrating a schematic configuration example of a vehicle control system, which is an example of a moving body control system to which the technology according to the present disclosure can be applied.

The vehicle control system 12000 includes a plurality of electronic control units connected thereto via a communication network 12001. In the example illustrated in FIG. 44, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, a sound/image output unit 12052, and an in-vehicle network interface (I/F) 12053 are illustrated.

The drive system control unit 12010 controls an operation of an apparatus related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information outside of the vehicle mounted with the vehicle control system 12000. For example, the vehicle exterior information detection unit 12030 is connected with the distance measurement device 12031. The distance measurement device 12031 includes the distance measurement device 1000. The vehicle exterior information detection unit 12030 has the distance measurement device 12031 measure the distance to an object outside of the vehicle (test object S) and obtains the resulting distance data. The vehicle exterior information detection unit 12030 may perform object detection processing for example for people, vehicles, obstacles, and signs on the basis of the obtained distance data.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of information inside and outside of the vehicle acquired by the vehicle exterior information detection unit 12030 or the vehicle interior information detection unit 12040, and output a control command to the drive system control unit 12010. For example, the microcomputer 12051 can perform cooperative control for the purpose of realizing functions of an ADAS (Advanced Driver Assistance System) including vehicle collision avoidance, impact mitigation, following traveling based on an inter-vehicle distance, vehicle speed maintenance driving, vehicle collision warning, vehicle lane deviation warning, and the like.

Further, the microcomputer 12051 can perform cooperative control for the purpose of automated driving or the like in which autonomous travel is performed without depending on operations of the driver, by controlling the driving force generator, the steering mechanism, or the braking device and the like on the basis of information about the surroundings of the vehicle, the information being acquired by the vehicle exterior information detection unit 12030 or the vehicle interior information detection unit 12040.

In addition, the microcomputer 12051 can output a control command to the body system control unit 12020 based on the information outside of the vehicle acquired by the vehicle exterior information detection unit 12030. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The sound/image output unit 12052 transmits an output signal of at least one of sound and an image to an output device capable of visually or audibly notifying a passenger or the outside of the vehicle of information. In the example in FIG. 44, an audio speaker 12061, a display unit 12062, and an instrument panel 12063 are illustrated as examples of the output device. For example, the display unit 12062 may include at least one of an on-board display and a head-up display.

FIG. 45 illustrates an example of installation position of the distance measurement device 12031.

In FIG. 45, a vehicle 12100 includes distance measurement devices 12101, 12102, 12103, 12104, and 12105 as the distance measurement device 12031.

The distance measurement devices 12101, 12102, 12103, 12104, and 12105 are provided at positions such as a front nose, side mirrors, a rear bumper, a back door, and an upper portion of a vehicle internal front windshield of the vehicle 12100. The distance measurement device 12101 provided on the front nose and the distance measurement device 12105 provided in an upper portion of the vehicle internal front windshield mainly acquire images in front of the vehicle 12100. The distance measurement devices 12102 and 12103 included in the side mirrors mainly acquire images of areas on the sides of the vehicle 12100. The distance measurement device 12104 included in the rear bumper or the back door mainly acquires an image of an area behind the vehicle 12100. Front view images acquired by the distance measurement devices 12101 and 12105 are mainly used for detection of preceding vehicles, pedestrians, obstacles, traffic lights, traffic signs, and the like.

FIG. 45 illustrates an example of detection ranges of the distance measurement devices 12101 to 12104. A detection range 12111 indicates an detection range by the distance measurement device 12101 provided at the front nose, detection ranges 12112 and 12113 respectively indicate detection ranges by the distance measurement devices 12102 and 12103 provided at the side-view mirrors, and an detection range 12114 indicates an detection range by the distance measurement device 12104 provided at the rear bumper or the back door.

For example, the microcomputer 12051 can extract, particularly a closest three-dimensional object on a path through which the vehicle 12100 is traveling, which is a three-dimensional object traveling at a predetermined speed (for example, 0 km/h or higher) in the substantially same direction as the vehicle 12100, as a vehicle ahead by obtaining a distance to each three-dimensional object in the detection ranges 12111 to 12114 and temporal change in the distance (a relative speed with respect to the vehicle 12100) based on distance information obtained from the distance measurement devices 12101 to 12104. The microcomputer 12051 can also set a following distance to the vehicle ahead to be maintained in advance and perform automatic brake control (including following stop control) and automatic acceleration control (including following start control). Thus, it is possible to perform cooperative control for the purpose of, for example, automated driving in which the vehicle travels in an automated manner without requiring the driver to perform operations.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the distance measurement devices 12101 to 12104 and can use the three-dimensional data to perform automated avoidance of obstacles. For example, the microcomputer 12051 identifies obstacles in the vicinity of the vehicle 12100 into obstacles that can be visually recognized by the driver of the vehicle 12100 and obstacles that are difficult to be visually recognized by the driver. Then, the microcomputer 12051 can determine a risk of collision indicating the degree of risk of collision with each obstacle and can perform driving assistance for collision avoidance by outputting a warning to the driver through the audio speaker 12061 or the display unit 12062 and performing forced deceleration or avoidance steering through the drive system control unit 12010 when the risk of collision has a value equal to or greater than a set value and there is a possibility of collision.

An example of the moving body control system to which the technology according to the present disclosure can be applied has been described above. The technology according to the present disclosure can be applied to the distance measurement device 12031 among the configurations described above.

In addition, the present technology can also have the following configurations.

(1) A surface emitting laser including a semiconductor multilayer film reflector,
a reflector,
an active layer provided between the semiconductor multilayer film reflector and the reflector, and
a metal film provided at a back surface of the semiconductor multilayer film reflector which is a surface on an opposite side to the side of the active layer or having a part provided on a virtual surface including the back surface on the opposite side to the side of the active layer and a further part provided in and/or around the semiconductor multilayer film reflector.

(2) The surface emitting laser according to (1), wherein the semiconductor multilayer film reflector includes amorphous layers and mixed crystal layers alternately stacked on each other.

(3) The surface emitting laser according to (1) or (2), wherein each of the amorphous layer is an InP layer, and each of the mixed crystal layer is an AlGaInAs layer.

(4) The surface emitting laser according to any one of (1) to (3), wherein the metal film has a part provided on a virtual surface including the back surface on the opposite side to the side of the active layer and a further part provided in and/or around the semiconductor multilayer film reflector, and the further part is in contact with a side surface of the semiconductor multilayer film reflector.

(5) The surface emitting laser according to any one of (1) to (4), wherein a hole is provided at the back surface of the semiconductor multilayer film reflector, and the further part of the metal film is fitted in the hole.

(6) The surface emitting laser according to (5), wherein the further part of the metal film is in contact with an inner surface of the hole.

(7) The surface emitting laser according to (5) or (6), wherein the hole penetrates the semiconductor multilayer film reflector.

(8) The surface emitting laser according to (5) or (6), wherein the hole does not penetrate the semiconductor multilayer film reflector.

(9) The surface emitting laser according to any one of (5) to (8), wherein the hole has a shape at least partly tapered or reversely tapered in side view.

(10) The surface emitting laser according to any one of (5) to (9), wherein the hole is provided around a region of the semiconductor multilayer film reflector corresponding to an emission region of the active layer.

(11) The surface emitting laser according to (10), wherein at least one of the holes is provided to surround the region of the semiconductor multilayer film reflector.

(12) The surface emitting laser according to any one of (5) to (11), wherein a plurality of the holes is provided.

(13) The surface emitting laser according to any one of (1) to (12), wherein first and second electrodes configured to inject current to the active layer are provided on a side of the semiconductor multilayer film reflector opposite to the back surface side.

(14) The surface emitting laser according to any one of (2) to (13), wherein the back surface of the semiconductor multilayer film reflector is one surface of one of the amorphous layers.

(15) The surface emitting laser according to (14), wherein the one of the amorphous layer has a thickness different from that of another amorphous layer of the semiconductor multilayer film reflector.

(16) The surface emitting laser according to any one of (1) to (15), wherein the metal film is made of one of Au, Ag, and Al.

(17) The surface emitting laser according to any one of (1) to (16), wherein the metal film has a stacked structure including a plurality of metal layers of different kinds of metal stacked on each other.

(18) The surface emitting laser according to any one of (2) to (17), wherein the amorous layer of a part of the semiconductor multilayer film reflector has an optical thickness represented by (m+2)λ/4(m>1) where the surface emitting laser has an oscillation wavelength λ.

(19) The surface emitting laser according to any one of (1) to (18), wherein the metal film and a substrate are bonded through another metal film.

(20) The surface emitting laser according to any one of (1) to (19), wherein the reflector is a dielectric multilayer film reflector.

(21) The surface emitting laser according to any one of (1) to (20), including a tunnel junction layer provided between the semiconductor multilayer film reflector and the reflector to set an emission region of the active layer.

(22) The surface emitting laser according to any one of (1) to (21), further including a substrate bonded to the metal film.

(23) A surface emitting laser array including a plurality of the surface emitting lasers according to any one of (1) to (22).

(24) An electronic device including a surface emitting laser according to any one of (1) to (22).

(25) A method for manufacturing a surface emitting laser, the method including forming, on a substrate, a structure including a semiconductor multilayer film reflector, an active layer, and a reflector in this order from the side of the substrate,
bonding a support substrate to a surface of the structure on the side of the reflector,
removing the substrate, and
forming a metal film on a back surface of the semiconductor multilayer film reflector which is a surface on an opposite side to the side of the active layer.

(26) The method for manufacturing a surface emitting laser according to (25), further including forming a hole at the back surface of the semiconductor multilayer film reflector between the removing step and the forming step,
wherein
the hole is filled with a part of the metal film in the forming step.

(27) The method for manufacturing a surface emitting laser according to (25) or

(26), further including bonding a holding substrate to the metal film and removing the support substrate.

### REFERENCE SIGNS LIST

10-1 to 10-20 Surface emitting laser
100 Another metal film
101 Substrate
102 Metal film
102a First part (part of metal film)
102b Second part (further part of metal film)
103 Semiconductor multilayer film reflector
103a Amorphous layer
103b Mixed crystal layer
105 Active layer
109 Anode electrode (first electrode)
110 Reflector
111 Penetrating electrode (second electrode)
H, H1 to H4 Hole

1. A surface emitting laser comprising: a semiconductor multilayer film reflector;
a reflector;
an active layer provided between the semiconductor multilayer film reflector and the reflector; and
a metal film provided at a back surface of the semiconductor multilayer film reflector which is a surface on an opposite side to the side of the active layer or having a part provided on a virtual surface including the back surface on the opposite side to the side of the active layer and a further part provided in and/or around the semiconductor multilayer film reflector.

2. The surface emitting laser according to claim 1, wherein the semiconductor multilayer film reflector includes amorphous layers and mixed crystal layers alternately stacked on each other.

3. The surface emitting laser according to claim 2, wherein each of the amorphous layer is an InP layer, and each of the mixed crystal layer is an AlGaInAs layer.

4. The surface emitting laser according to claim 1, wherein the metal film has the part provided on the virtual surface including the back surface on the opposite side to the side of the active layer and the further part provided in and/or around the semiconductor multilayer film reflector, and
the further part of the metal film is in contact with a side surface of the semiconductor multilayer film reflector.

5. The surface emitting laser according to claim 1, wherein a hole is provided at the back surface of the semiconductor multilayer film reflector, and
the further part of the metal film is fitted in the hole.

6. The surface emitting laser according to claim 5, wherein the further part of the metal film is in contact with an inner surface of the hole.

7. The surface emitting laser according to claim 5, wherein the hole penetrates the semiconductor multilayer film reflector.

8. The surface emitting laser according to claim 5, wherein the hole does not penetrate the semiconductor multilayer film reflector.

9. The surface emitting laser according to claim 5, wherein the hole has a shape at least partly tapered or reversely tapered in side view.

10. The surface emitting laser according to claim 5, wherein the hole is provided around a region of the semiconductor multilayer film reflector corresponding to an emission region of the active layer.

11. The surface emitting laser according to claim 10, wherein at least one of the holes is provided to surround the region of the semiconductor multilayer film reflector.

12. The surface emitting laser according to claim 11, wherein a plurality of the holes is provided.

13. The surface emitting laser according to claim 1, wherein first and second electrodes configured to inject current to the active layer are provided on a side of the semiconductor multilayer film reflector opposite to the back surface side.

14. The surface emitting laser according to claim 2, wherein the back surface of the semiconductor multilayer film reflector is one surface of one of the amorphous layers.

15. The surface emitting laser according to claim 14, wherein the one of the amorphous layer has a thickness different from that of another amorphous layer of the semiconductor multilayer film reflector.

16. The surface emitting laser according to claim 1, wherein the metal film is made of one of Au, Ag, and Al.

17. The surface emitting laser according to claim 1, wherein the metal film has a stacked structure including a plurality of metal layers of different kinds of metal stacked on each other.

18. The surface emitting laser according to claim 2, wherein the amorous layer of a part of the semiconductor multilayer film reflector has an optical thickness represented by (m+2)λ/4(m>1) where the surface emitting laser has an oscillation wavelength λ.

19. The surface emitting laser according to claim 1, wherein the metal film and a substrate are bonded through another metal film.

20. The surface emitting laser according to claim 1, wherein the reflector is a dielectric multilayer film reflector.
